(19) United States
(12) Patent Application Publication
(10) Pub. No.: US 2025/0364969 A1
(43) Pub. Date: Nov. 27, 2025

(54) ELASTIC WAVE DEVICE

(71) Applicant: Murata Manufacturing Co., Ltd., Nagaokakyo-shi (JP)

(72) Inventors: Motoji TSUDA, Nagaokakyo-shi (JP); Makoto SAWAMURA, Nagaokakyo-shi (JP); Katsuhito KURODA, Nagaokakyo-shi (JP); Masashi OMURA, Nagaokakyo-shi (JP); Hirotsugu MORI, Nagaokakyo-shi (JP); Kazumasa HARUTA, Nagaokakyo-shi (JP); Toru KIZU, Nagaokakyo-shi (JP); Yasuyuki IDA, Nagaokakyo-shi (JP); Chihiro MURATA, Nagaokakyo-shi (JP); Eiji FUJIMORI, Nagaokakyo-shi (JP); Katsumi SUZUKI, Nagaokakyo-shi (JP); Yutaka KISHIMOTO, Nagaokakyo-shi (JP); Hiroshi SOMADA, Nagaokakyo-shi (JP); Daisuke MORIHARA, Nagaokakyo-shi (JP); Kentarou DEHARA, Nagaokakyo-shi (JP); Mitsuyuki TANAKA, Nagaokakyo-shi (JP); Manabu NAKAHORI, Nagaokakyo-shi (JP)

(21) Appl. No.: 19/293,584

(22) Filed: Aug. 7, 2025

Related U.S. Application Data
(63) Continuation of application No. PCT/US2024/018257, filed on Mar. 1, 2024.
(60) Provisional application No. 63/449,674, filed on Mar. 3, 2023.

(51) Int. Cl. H03H 9/10; H03H 9/05; H03H 9/125

(52) U.S. Cl. CPC H03H 9/1014; H03H 9/125; H03H 9/0514

(57) ABSTRACT

An acoustic wave device includes an insulating layer and a piezoelectric layer defining a cavity, a first excitation electrode on a first surface of the piezoelectric layer opposite to the cavity, a second excitation electrode on a second surface of piezoelectric layer and within the cavity, a wiring electrode on the piezoelectric layer and connected to the first excitation electrode, a lid, a conductive wall extending between a first portion of the wiring electrode and the lid, and a sealing frame extending between a second portion of the wiring electrode and the lid. A first width of a first portion of the sealing frame is larger than a second width of a second portion of the sealing frame. A third width of the second portion of the wiring electrode is smaller than the first width and is larger than the second width.

### CROSS REFERENCE TO RELATED APPLICATIONS

This application claims the benefit of priority to U.S. Provisional Application No. 63/449,674 filed on Mar. 3, 2023 and is a Continuation Application of PCT Application No. PCT/US2024/018257 filed on Mar. 1, 2024. The entire contents of each application are hereby incorporated herein by reference.

### BACKGROUND OF THE INVENTION

### 1. Field of the Invention

The present invention relates to elastic wave devices and filter devices.

### 2. Description of the Related Art

Conventionally, an elastic wave device is widely used for a filter of a mobile telephone. Japanese Patent Application Laid-Open No. 2020-141337 discloses an example of a piezoelectric thin film resonator as an elastic wave device. In the piezoelectric thin film resonator, a piezoelectric film is provided on a substrate. Electrodes provided on both main surfaces of the piezoelectric film face each other. The region where the electrodes face each other is the resonance region. Each of the electrodes includes an extended portion extending from the resonance region. The extended portion connects to another piezoelectric thin film resonator. The substrate is provided with a cavity. The resonance region faces the cavity.

### SUMMARY OF THE INVENTION

Example embodiments of the present invention provide acoustic wave devices that each reduce or prevent capacitive coupling between a conductive wall and a sealing frame of the acoustic wave devices.

According to an example embodiment of the present invention, an acoustic wave device includes an insulating layer including a recess, a piezoelectric layer on the insulating layer and over the recess to define a cavity, a first excitation electrode on a first surface of the piezoelectric layer opposite to the cavity, a second excitation electrode within the cavity and on a second surface of the piezoelectric layer opposite to the first surface, a dielectric layer on the first excitation electrode, and a first frame on the second excitation electrode and within the cavity.

The first frame may include first width portions and second width portions different from the first width portions.

The acoustic wave device may further include a second frame on the second excitation electrode. The second frame may be on a first surface of the second excitation electrode between the piezoelectric layer and the second excitation electrode, and the first frame may be on a second surface of the second excitation electrode opposite to the first surface of the second excitation electrode. The acoustic wave device may further include an excitation region defined by an overlap region, when viewed in a plan view, between the first and the second excitation electrodes. The second frame may include a cantilever that extends past an end of the second excitation electrode. The first frame may have a constant width and may extend along an entire or substantially an entire periphery of the excitation region, and the second frame may have a constant width and may extend along a portion of the periphery of the excitation region. The first frame may include first width portions and second width portions different from the first width portions and may extend along an entire or substantially an entire periphery of the excitation region, and the second frame may have a constant width and may extend along the entire or substantially the entire periphery of the excitation region. The first frame may have a constant width and may extend along a first portion of an entire or substantially an entire periphery of the excitation region, and the second frame may have a constant width and may extend along a second portion of the entire or substantially the entire periphery of the excitation region. The first frame may include first width portions and second width portions different from the first width portions and may extend along a first portion of an entire or substantially an entire periphery of the excitation region, and the second frame may have a constant width and may extend along a second portion of the entire or substantially the entire periphery of the excitation region.

The recess may have a tapered shape toward a bottom surface of the recess. The recess may include a step that is underneath the end of the second excitation electrode. The acoustic wave device may further include a first wiring electrode connected to the first excitation electrode and having a first thickness and a second wiring electrode connected to the second excitation electrode and having a second thickness that may be smaller than the first thickness. The acoustic wave device may further include a first wiring electrode connected to the first excitation electrode and a second wiring electrode embedded in the insulating layer such that one surface of the second wiring electrode may contact the second excitation electrode and other surfaces of the second wiring electrode can contact the insulating layer. The second wiring electrode may be located outside the cavity. The first wiring electrode may be located outside the cavity. A total area of the first excitation electrode and the first wiring electrode may be larger than a total area of the second excitation electrode and the second wiring electrode. The piezoelectric layer may be pyro-free. The piezoelectric layer may include first and second etching holes arranged along a direction in which a coefficient of linear expansion is largest.

According to an example embodiment, an acoustic wave device includes an insulating layer including a recess, a piezoelectric layer on the insulating layer and over the recess to define a cavity, a first excitation electrode on a first surface of the piezoelectric layer opposite to the cavity, a second excitation electrode within the cavity and on a second surface of the piezoelectric layer opposite to the first surface, a wiring electrode on the piezoelectric layer and connected to the first excitation electrode, a lid, a conductive wall extending between a first portion of the wiring electrode and the lid, and a sealing frame extending between a second portion of the wiring electrode and the lid. The conductive wall includes a first portion and a second portion, and the sealing frame includes a first portion with a first width and a second portion with a second width smaller than the first width. A third width of the second portion of the wiring electrode is smaller than the first width of the first portion of the sealing frame and is larger than the second width of the second portion of the sealing frame.

The acoustic wave device may further include a first dielectric layer between the lid and the conductive wall and a second dielectric layer between the lid and the sealing frame. The first portion of the conductive wall may have a tapered shape that narrows towards the second portion of the conductive wall, the second portion of the conductive wall may have a tapered shape that narrows towards the first portion of the conductive wall, the first portion of the sealing frame may have a tapered shape that narrows towards the second portion of the sealing frame, and the second portion of the sealing frame may have a tapered shape that narrows towards the first portion of the sealing frame. The lid may include a via connected to the first portion of the conductive wall. The acoustic wave device may further include a third dielectric layer between the via and the lid. The third dielectric layer may include silicon oxide.

The first portion of the conductive wall may include multiple layers that include a first gold layer, the second portion of the conductive wall may include multiple layers that include a second gold layer directly connected to the first gold layer of the first portion of the conductive wall, the first portion of the sealing frame may include multiple layers that include a third gold layer, and the second portion of the sealing frame may include multiple layers that include a fourth gold layer directly connected to the third gold layer of the first portion of the sealing frame.

The first portion of the conductive wall may include an extending portion that extends past an end of the second portion of the conductive wall closest to the sealing frame towards the sealing frame with a fourth width, the wiring electrode may include a first extending portion that extends past the end of the second portion of the conductive wall closest to the sealing frame toward the sealing frame with a fifth width that is less than the fourth width, the first portion of the sealing frame may include an extending portion that extends past an end of the second portion of the sealing frame towards the conductive wall with a sixth width, and the wiring electrode may include a second extending portion that extends past the end of the second portion of the sealing frame towards the conductive wall with a seventh width that is less than the sixth width.

The first portion of the conductive wall may include a first platinum layer adjacent to a first gold layer, the second portion of the conductive wall may include a second platinum layer adjacent to a second gold layer, the first portion of the sealing frame may include a third platinum layer adjacent to a third gold layer, and the second portion of the sealing frame may include a fourth platinum layer adjacent to a fourth gold layer.

The acoustic wave device may further include a support substrate on which the insulating layer can be located, wherein the support substrate may include a step at an end of the support substrate.

The first portion of the conductive wall may include multiple layers that include a first gold layer, the second portion of the conductive wall may include multiple layers that include a second gold layer directly connected to the first gold layer of the first portion of the conductive wall, the first portion of the sealing frame may include multiple layers that include a first gold layer, and the second portion of the sealing frame may include multiple layers that include a second gold layer directly connected to the first gold layer of the first portion of the sealing frame.

The acoustic wave device may further include a dielectric layer on the first excitation electrode and a first frame on the second excitation electrode and within the cavity.

The first frame may include first width portions and second width portions different from the first width portions.

The acoustic wave device may further include a second frame on the second excitation electrode. The second frame may be on a first surface of the second excitation electrode between the piezoelectric layer and the second excitation electrode, and the first frame may be on a second surface of the second excitation electrode opposite to the first surface of the second excitation electrode. The acoustic wave device may further include an excitation region defined by an overlap region, when viewed in a plan view, between the first and the second excitation electrodes. The second frame may include a cantilever that extends past an end of the second excitation electrode. The first frame may have a constant width and may extend along an entire or substantially an entire periphery of the excitation region, and the second frame may have a constant width and may extend along a portion of the periphery of the excitation region. The first frame may include first width portions and second width portions different from the first width portions and may extend along an entire or substantially an entire periphery of the excitation region, and the second frame may have a constant width and can extend along the entire or substantially the entire periphery of the excitation region. The first frame may have a constant width and may extend along a first portion of an entire or substantially an entire periphery of the excitation region, and the second frame may have a constant width and may extend along a second portion of the entire or substantially the entire periphery of the excitation region. The first frame includes first width portions and second width portions different from the first width portions and may extend along a first portion of an entire or substantially an entire periphery of the excitation region, and the second frame may have a constant width and can extend along a second portion of the entire or substantially the entire periphery of the excitation region.

The above and other elements, features, steps, characteristics and advantages of the present invention will become more apparent from the following detailed description of the example embodiments with reference to the attached drawings.

### BRIEF DESCRIPTION OF THE DRAWINGS

FIGS. 1A-1H show an elastic wave device according to a first example embodiment of the present invention. FIG. 1A is a cross-sectional schematic drawing of the acoustic wave device. FIG. 1B is a plan-view schematic design drawing of a portion of the acoustic wave device. FIG. 1C is a trace drawing of a cross-sectional photograph of a portion of the acoustic wave device. FIGS. 1D and 1E are close-up cross-sectional schematic drawings of portions of the acoustic wave device. FIGS. 1F and 1G are close-up cross-sectional schematic drawings of the conductive wall and the sealing frame of the acoustic wave device. FIG. 1H is a plan-view schematic design drawing of the acoustic wave device.

FIGS. 2A-2C show a cavity, an etching hole, and a piezoelectric layer of the elastic wave device of FIG. 1H. FIGS. 2A and 2C are plan-view schematic drawings. FIG. 2B is a trace drawing of a plan-view photograph.

FIG. 3A is a cross-sectional schematic drawing of a portion of the elastic wave device of FIG. 1H on a plane crossing two etching holes. FIG. 3B is a plan-view schematic drawing of the portion of the elastic wave device. FIG. 3C is trace drawings of a cross-sectional photograph. FIG. 3D is a trace drawing of an enlarged portion of FIG. 3C.

FIG. 4A is a trace drawing of a cross-sectional photograph of a first excitation electrode, and FIG. 4B is a trace drawing of a cross-sectional photograph of a second excitation electrode.

FIG. 5 is a trace drawing of an enlarged photograph of a cross section of a first wiring electrode.

FIGS. 6A-6E show an example of a first frame and a second frame of the first example embodiment of the present invention. FIG. 6A is a trace drawing of a plan-view photograph of an excitation region A. FIGS. 6B and 6C are trace drawings of cross-sectional photographs showing the first frame and the second frame of FIG. 6A. FIG. 6D is a plan-view schematic drawing of the excitation region A of FIG. 6A. FIG. 6E is a cross-sectional schematic drawing of the first frame and the second frame of FIG. 6D.

FIG. 7A is a trace drawing of a cross-sectional photograph of the first frame, the first excitation electrode, and the second frame. FIG. 7B is a cross-sectional schematic drawing of the first frame, the first excitation electrode, and the second frame.

FIG. 8A is a cross-sectional schematic drawing of the structure of the elastic wave device. FIG. 8B is a trace drawing of a cross-sectional photograph of the structure of the elastic wave device.

FIG. 9A is a cross-sectional view of the first wiring electrode, the conductive wall, and the sealing frame. FIG. 9B is a plan view of the first wiring electrode, the conductive wall, and the sealing frame.

FIG. 10A and 10B are a cross-sectional view and a plan view of another example of a elastic wave device according to an example embodiment of the present invention.

FIG. 11A is a sectional view showing the first frame, the second frame, and the second excitation electrode. FIGS. 11B-11E are trace drawings of cross-sectional photographs showing the first frame, the second frame, and the second excitation electrode.

FIG. 12 is a plan-view schematic drawing showing Arrangement A with a normal first frame.

FIGS. 13A and 13B are plan-view and cross-sectional-view schematic drawings showing Arrangement B with a jagged first frame.

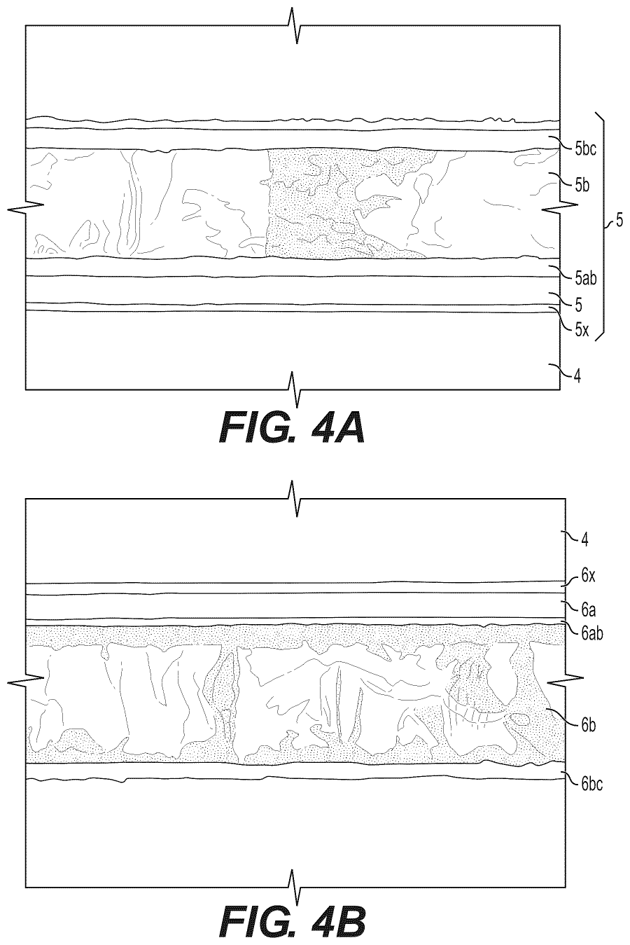

FIG. 4 is a plan-view schematic drawing showing Arrangement C with a second frame with a dielectric cantilever under an excitation electrode.

FIG. 15A is plan-view schematic drawing showing Arrangement D with a circular shape and with a normal first frame and a second frame with a dielectric cantilever. FIG. 15B is a trace drawing of a plan-view photograph showing Arrangement D of FIG. 15A.

FIG. 16A is plan-view schematic drawing showing Arrangement D with a rectangular or substantially rectangular shape and with a normal first frame and a second frame with a dielectric cantilever. FIG. 16B is a trace drawing of a plan-view photograph showing Arrangement D of FIG. 16A.

FIG. 17A is a plan-view schematic drawing showing Arrangement E with a circular or substantially circular shape and with a jagged first frame and a second frame with a dielectric cantilever. FIG. 17B is a trace drawing of a plan-view photograph showing Arrangement E of FIG. 17A.

FIG. 18A is a plan-view schematic drawing showing Arrangement E with a rectangular or substantially rectangular shape and with a jagged first frame and a second frame with a dielectric cantilever. FIG. 18B is a trace drawing of a plan-view photograph showing Arrangement D of FIG. 18A.

FIG. 19A is a plan-view schematic drawing showing Arrangement F with a circular or substantially circular shape and with a normal first frame and a second frame with a dielectric cantilever. FIG. 19B is a trace drawing of a plan-view photograph showing Arrangement F of FIG. 19A.

FIG. 20 is a plan-view schematic drawing showing Arrangement G with a jagged first frame and a second frame with a dielectric cantilever.

### DETAILED DESCRIPTION OF THE EXAMPLE EMBODIMENTS

Hereinafter, the present invention will be clarified by describing specific example embodiments of the present invention with reference to the drawings. Each of the example embodiments described herein is illustrative and partial replacement or combination of configurations is possible between different example embodiments.

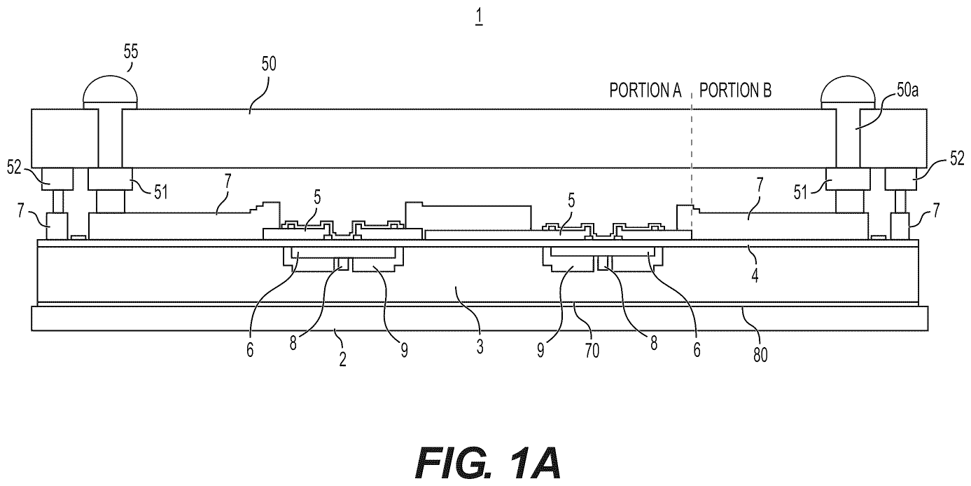

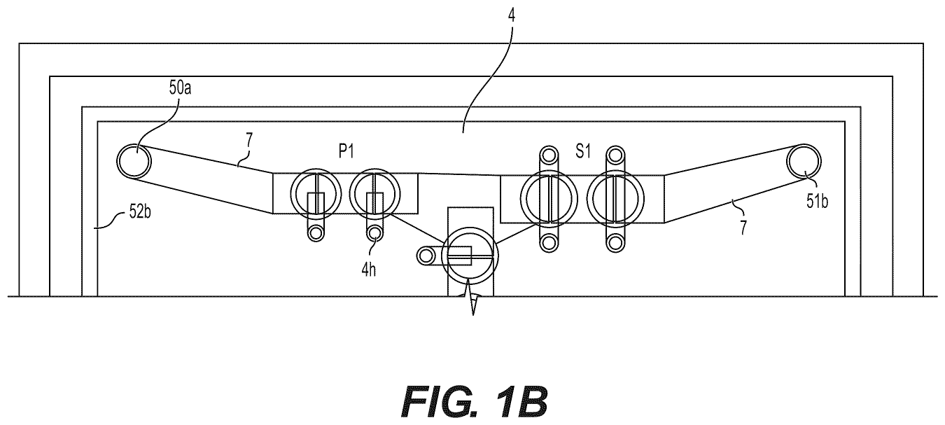

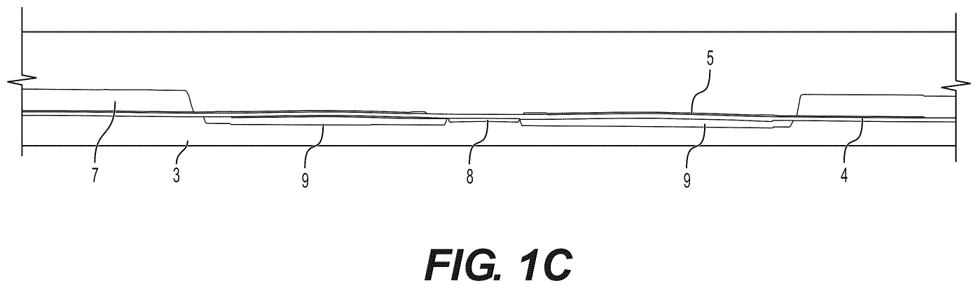

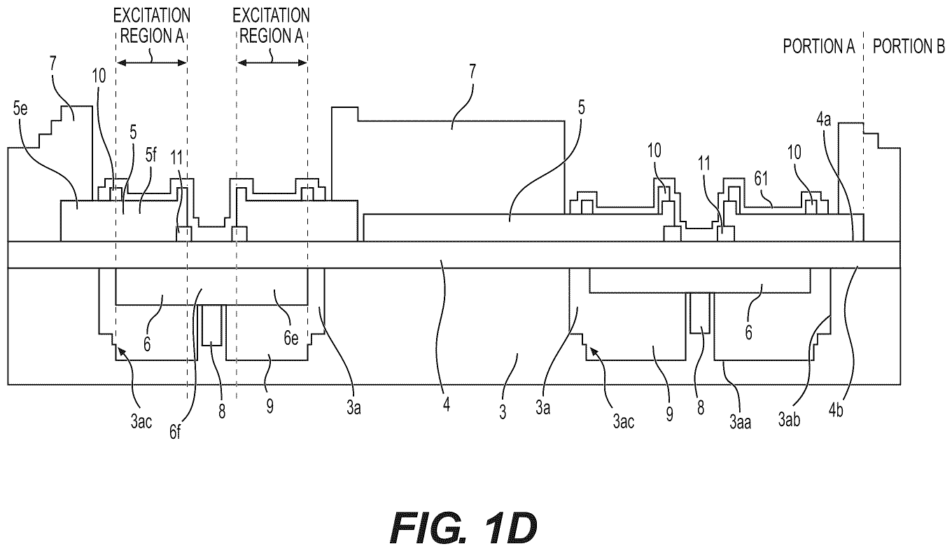

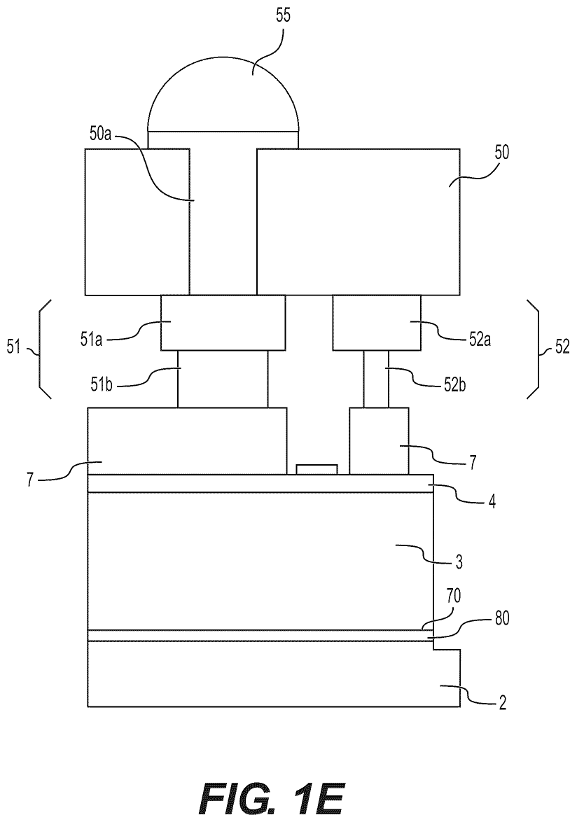

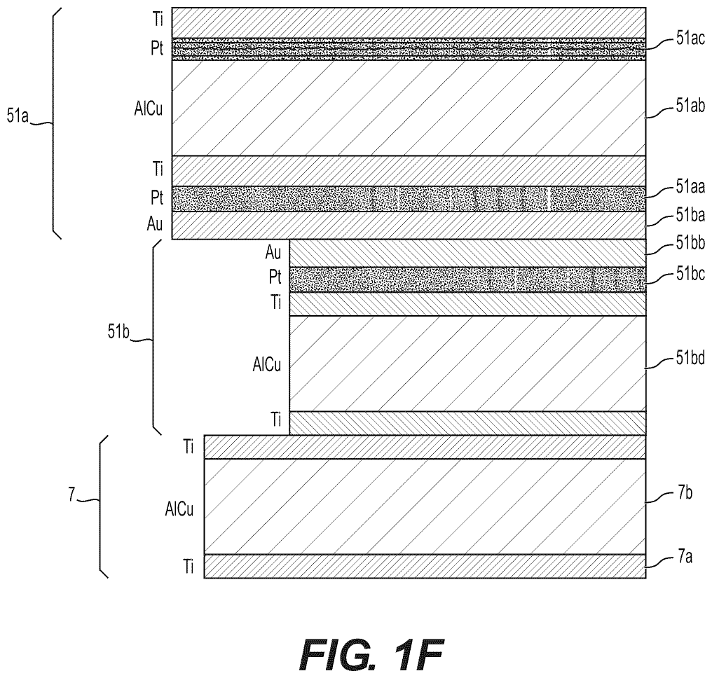

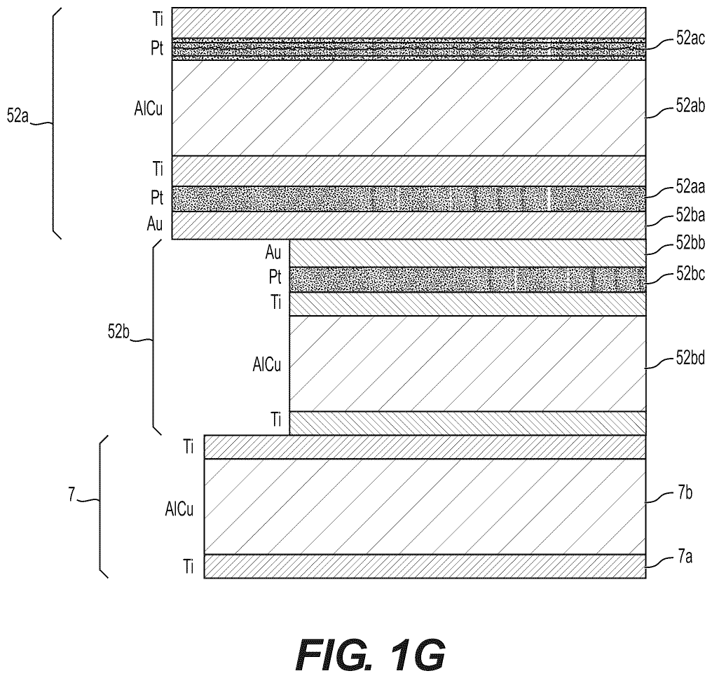

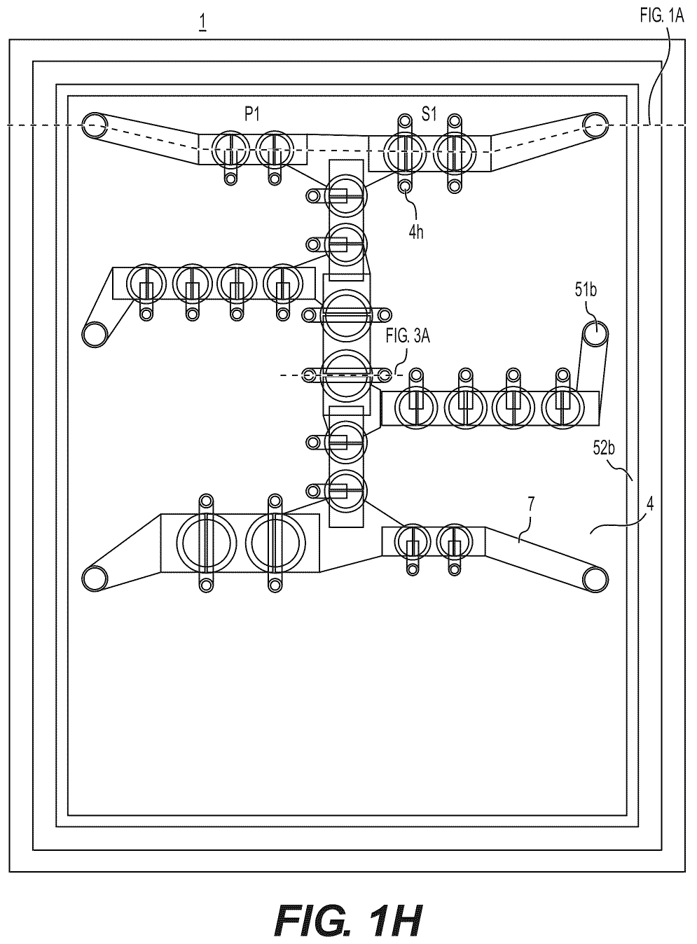

FIGS. 1A-1H show an elastic wave device 1 according to a first example embodiment of the present invention. FIG. 1A is a cross-sectional schematic drawing of the acoustic wave device 1. FIG. 1B is a plan-view schematic design drawing of a portion of the acoustic wave device 1. FIG. 1B includes some lines that do not exist in actual products. FIG. 1C is a trace drawing of a cross-sectional photograph of a portion of the acoustic wave device 1. FIGS. 1D and 1E are close-up cross-sectional schematic drawings of portions of the acoustic wave device 1. FIGS. 1F and 1G are close-up cross-sectional schematic drawings of the conductive wall 51 and the sealing frame 52 of the acoustic wave device 1. FIG. 1H is a plan design view of the acoustic wave device 1. FIG. 1H includes some lines that do not exist in actual products.

The elastic wave device 1 of the present example embodiment is a bulk acoustic wave (BAW) element. The elastic wave device 1 includes a support substrate 2, an insulating layer 3, a piezoelectric layer 4, a first excitation electrode 5, a second excitation electrode 6, a first wiring electrode 7, and a second wiring electrode 8. The first excitation electrode 5 and the second excitation electrode 6 are on opposite sides of the piezoelectric layer 4. The region where the piezoelectric layer 4, the first excitation electrode 5, and the second excitation electrode 6 overlap is the excitation region A. By applying an alternating electric field between the first excitation electrode 5 and the second excitation electrode 6, an elastic wave is excited in the excitation region A.

A cavity 9 is an acoustic reflection portion that is included in the elastic wave device 1. The cavity 9 is surrounded by an insulating layer 3, a piezoelectric layer 4, and a second excitation electrode 6.

An insulating layer 3 is provided on the support substrate 2. For example, silicon, aluminum oxide, quartz, alumina, sapphire, diamond, gallium nitride, glass, or the like can be used as the material of the support substrate 2. In the present example embodiment, the support substrate 2 includes silicon, for example.

In the present example embodiment, a protective layer 70 to protect the support substrate 2 is included between the support substrate 2 and the insulating layer 3. The material of the protective layer 70 can be, for example, silicon oxide, silicon nitride, or the like, and in the present example embodiment, the protective layer 70 includes silicon nitride, for example. A trap-rich layer 80 is located between the support substrate 2 and the protective layer 70 to ensure the high-resistivity characteristic of the support substrate 2. In the present example embodiment, the trap-rich layer 80 is formed by roughening the silicon surface of the support substrate 2. Any appropriate roughening method, such as, for example, reactive ion etching (RIE) or polishing, can be used to form the trap-rich layer 80. Forming, for example, a polycrystalline silicon film can create a trap-rich layer 80 without roughening the silicon surface.

The insulating layer 3 is located on the support substrate 2. The insulating layer 3 supports the piezoelectric layer 4, the first excitation electrode 5, and the second excitation electrode 6.

The insulating layer 3 includes a recess 3a. The recess 3a and the piezoelectric layer 4 define the cavity 9, with the second excitation electrode 6 being located within the cavity 9. When viewed from the upper side of FIG. 1A (i.e., in a plan view), the opening of the recess 3a is larger than the excitation region A. That is, in the present example embodiment, the cavity 9 is larger than the excitation region A.

As the material of the insulating layer 3, for example, a suitable dielectric, such as silicon oxide, tantalum pentoxide, or silicon nitride, can be used. In the present example embodiment, the insulating layer 3 includes silicon oxide, for example.

As shown in FIG. 1C, the recess 3a includes a bottom surface 3aa and a side surface 3ab. In the present example embodiment, the recess 3a has a tapered shape toward the bottom surface 3aa such that the recess 3a becomes smaller toward the bottom surface 3aa. In other words, a side wall of the recess 3a is tilted inwards toward the bottom surface 3aa. The bottom surface 3aa is larger than the excitation region A. The tapered shape of the recess 3a is not necessary, and the recess 3a can have any suitable shape.

A step 3ac connected between the bottom surface 3aa and the side surface 3ab is included in the recess 3a. As shown in FIGS. 1A and 1C, the step 3ac (not labeled in FIG. 1C but visible on the bottom surface 3aa) follows the step defined by the second excitation electrode 6 and the piezoelectric layer 4. The step 3ac can be underneath the end of the second excitation electrode 6 when viewed in a plan view, and the vertical surface of the step 3ac and the vertical surface of the end of the second excitation electrode 6 face each other or are orientated in opposite directions. Because the step 3ac is provided in the recess 3a, even when the piezoelectric layer 4 is deflected or deformed toward the recess 3a, it is possible to reduce or prevent the piezoelectric layer 4 coming into contact with the bottom surface 3aa, which could cause a malfunction.

The elastic wave device 1 can include an acoustic reflection portion that confines the energy of the elastic wave generated in the excitation region A to the excitation region A by reflecting elastic waves back into the excitation region A. The acoustic reflection portion can have a different acoustic velocity than the piezoelectric layer 4 so that the elastic waves are reflected back into excitation region A. Any suitable acoustic reflection portion can be used, including, for example, a cavity or an acoustic reflection film. In the first example embodiment shown in FIGS. 1A, 1C, and 1D, the acoustic reflection portion is the cavity 9, but it is also possible to use other acoustic reflection portions, such as an acoustic reflection film, for example. The acoustic reflection film can include one or more metal layers.

In the example embodiment of FIGS. 1A-1H, the cavity 9 can define the acoustic reflection portion of the elastic wave device 1. The cavity 9 overlaps the excitation region A in plan view. Thus, the energy of the elastic wave generated in the excitation region A can be suitably confined. A plan view as used herein means a view from a direction corresponding to the upper side in FIG. 1A or corresponding to the view shown in FIG. 1H, which is a plan view of the acoustic wave device 1. For example, in FIG. 1A, between the piezoelectric layer 4 side and the support substrate 2 side, the piezoelectric layer 4 side is upward.

The cavity 9 may overlap at least a portion of the excitation region A in plan view. For example, in plan view, a portion of the outer peripheral edge of the cavity 9 may be located outside the outer peripheral edge of the excitation region A, and another portion of the outer peripheral edge of the cavity 9 may be located inside the outer peripheral edge of the excitation region A. Alternatively, the cavity 9 can overlap the entire or substantially the entire excitation region A in plan view. Thus, the energy of the elastic wave can be effectively confined in the excitation region A. In the present example embodiment, the cavity 9 is larger than the excitation region A in plan view.

The shape of the cavity 9, in plan view, may be, for example, circular, rectangular, elliptical, or polygonal, or a combination thereof, in accordance with the excitation region A. In the case of a rectangular or polygonal shape, the corners may be curved. When the piezoelectric layer 4 is anisotropic and has a direction with the largest linear expansion coefficient in the plane defined by the piezoelectric layer 4, the cavity 9 can reduce or prevent the fracture of the piezoelectric layer 4 if the cavity 9 has an elliptical shape with the minor axis of the ellipsis aligned with the direction of the largest linear expansion coefficient. When the cavity 9 is rectangular, the same or substantially the same advantageous effects can be achieved by aligning the short side of the rectangle with the direction of the largest linear expansion coefficient. When the cavity 9 is polygonal, the same or substantially the same advantageous effects are achieved by aligning the shortest distance between any two vertices of the polygon with the direction of the largest linear expansion coefficient.

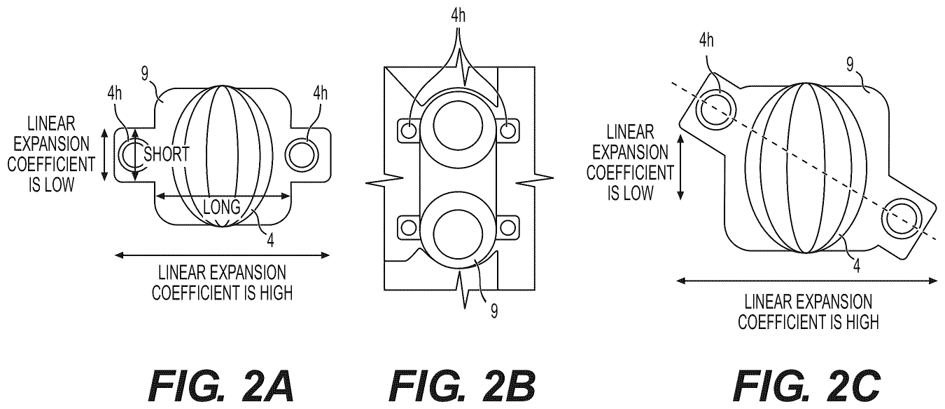

FIGS. 2A-2C show the piezoelectric layer 4, the cavity 9, and the etching hole 4h to be described later. FIGS. 2A and 2C are plan views showing the cavity 9, the etching hole 4h, and the piezoelectric layer 4, and FIG. 2B is a trace drawing of a plan photographic view showing the cavity 9, the etching hole 4h, and the piezoelectric layer 4.

As shown in FIG. 2C, the cavity 9 may be disposed obliquely to the direction with the largest coefficient of linear expansion. In other words, the direction in which the etching holes 4h are aligned may be oblique to the direction with the largest coefficient of linear expansion. The oblique arrangement of the etching holes 4h can be any suitable angle and is not limited to the approximately 45° shown in FIG. 2C.

As shown in FIG. 1A, the piezoelectric layer 4 is provided on the insulating layer 3. That is, the piezoelectric layer 4 is supported by the insulating layer 3. More specifically, in the present example embodiment, as seen in FIG. 1A, the ends of the piezoelectric layer 4 are on the insulating layer 3.

The piezoelectric layer 4 includes a first main surface 4a and a second main surface 4b. The first main surface 4a and the second main surface 4b are opposed to each other. Between the first main surface 4a and the second main surface 4b, the second main surface 4b is located on the same side as the insulating layer 3.

The material of the piezoelectric layer 4 can be, for example, lithium niobate, lithium tantalate, zinc oxide, aluminum nitride, quartz, or PZT (lead zirconate titanate). The material of the piezoelectric layer 4 can be, for example, lithium tantalate, lithium niobate, or can be an anisotropic substrate such as oriented aluminum nitride, PZT, or quartz. In the present example embodiment, the thickness of lithium niobate in the piezoelectric layer 4 is, for example, in the range of about 400 nm to about 500 nm, within manufacturing and/or measurement tolerances, but the film thickness is not limited to this range, and can be changed according to the material and/or the frequency used.

The piezoelectric layer 4 of the present example embodiment can be, for example, pyro-free lithium niobate or lithium tantalate. If the piezoelectric layer 4 is lithium niobate, then the piezoelectric layer 4 can be considered pyro-free if the pyroelectric effect is, for example, in the range of about 0.6×10⁻¹⁰ S/cm to about 3.4×10⁻⁹ S/cm, within measurement tolerances as measured by applying a voltage with a conductivity meter. If the piezoelectric layer 4 is lithium tantalate, then the piezoelectric layer 4 can be considered pyro-free if the pyroelectric effect is, for example, in the range of about 1.0×10⁻¹² S/cm to about 7.5×10⁻¹⁰ S/cm, within measurement tolerances as measured by applying a voltage with a conductivity meter. Thus, it is possible to reduce or prevent damage to and the destruction of the piezoelectric layer 4. The pyro-free treatment can be used for lithium niobate and lithium tantalate, which have large pyroelectric properties, and the fracture of the piezoelectric layer 4 can be reduced or prevented.

An etching hole 4h is included in the piezoelectric layer 4, and the etching hole 4h is used to provide the cavity 9. A plurality of etching holes 4h may be provided. When the piezoelectric layer 4 is anisotropic and has a direction with the largest linear expansion coefficient in the plane defined by the piezoelectric layer 4, as shown in FIGS. 2A-2C, the plurality of etching holes 4h can be aligned in a direction with the largest linear expansion coefficient of the piezoelectric layer 4. Thus, even if the piezoelectric layer 4 includes a material having anisotropy in the coefficient of linear expansion, the operation failure of the piezoelectric layer 4 can be reduced or prevented.

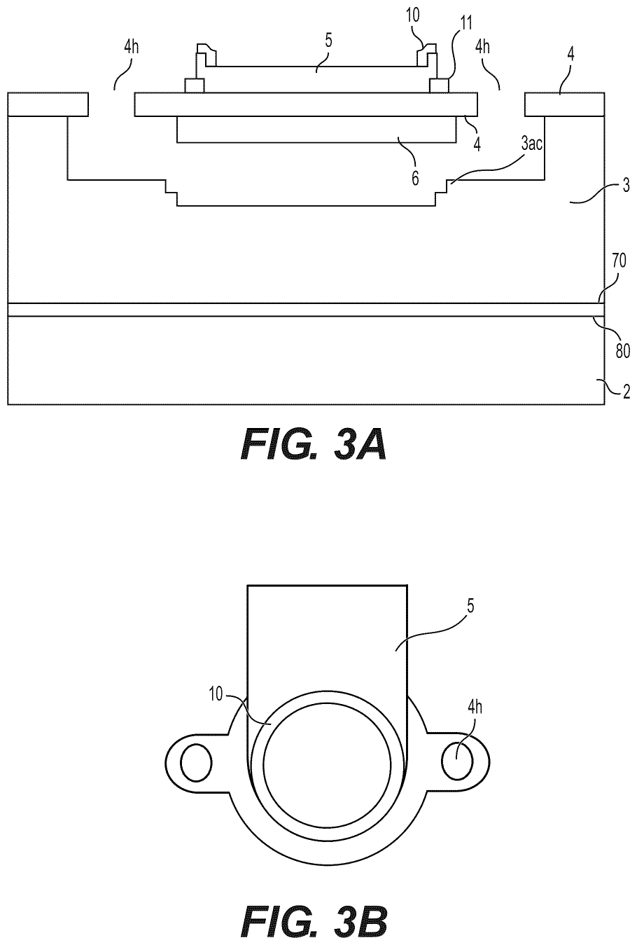

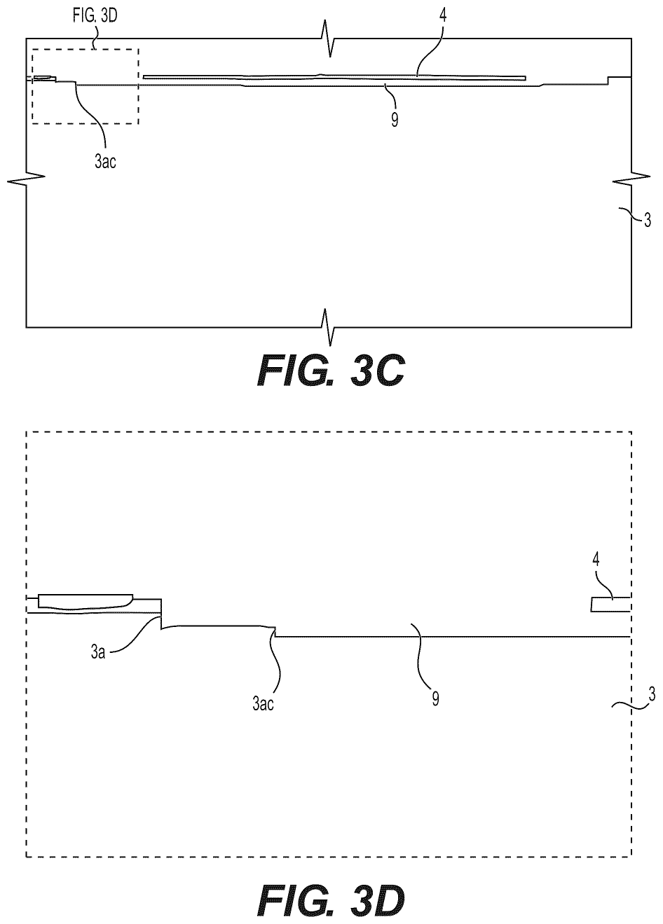

FIG. 3A is a cross-sectional view across a plurality of etching holes 4h, FIG. 3B is a plan view showing two etching holes 4h, FIG. 3C is a trace drawing of a cross-sectional photograph across two etching holes 4h, and FIG. 3D is a trace drawing an enlarged photograph of FIG. 3C. FIG. 3A is a cross-sectional view of FIG. 3B along dashed line. As shown in FIG. 3D, the etching hole 4h may be tapered. That is, the etching hole 4h may include an inclined wall surface, for example.

The first excitation electrode 5 is provided on the first main surface 4a of the piezoelectric layer 4. The first excitation electrode 5 need not cover all of the first main surface 4a. For example, as shown in FIG. 1A, the first excitation electrode 5 does not cover the end of the first main surface 4a. For example, the first main surface 4a may not be covered by the first excitation electrode 5 in the regions exterior to the resonators, including, as shown in FIG. 1B, the regions exterior to the parallel resonator P1 and series resonator S1. In FIG. 1A, both ends of the first main surface 4a are exposed from the first excitation electrode 5.

Further, in the region overlapping the cavity 9, the first excitation electrode 5 need not cover all of the first main surface 4a. In other words, in the region overlapping the cavity 9, the first main surface 4a includes an exposed portion not covered by the first excitation electrode 5.

The second excitation electrode 6 is provided on the second main surface 4b of the piezoelectric layer 4. The second excitation electrode 6 need not cover all of the second main surface 4b. For example, as shown in FIG. 1A, the second excitation electrode 6 does not cover portions of the second main surface 4b in the regions exterior to the resonators, including, as shown in FIG. 1B, the regions exterior to the parallel resonator P1 and series resonator S1. In other words, the second main surface 4b is not fully covered by the second excitation electrode 6.

Further, in the region overlapping the cavity 9, the second excitation electrode 6 need not cover all of the second main surface 4b. In other words, in the region overlapping the cavity 9, the second main surface 4b includes an exposed portion not covered by the second excitation electrode 6 along the periphery of the cavity 9. The exposed portion faces the step 3ac of the recess 3a.

The first excitation electrode 5 includes a fixed portion 5f supported by the insulating layer 3 and an open portion 5e overlapping the cavity 9. The second excitation electrode 6 includes a fixed portion of supported by the insulating layer 3 and an open portion 6e overlapping the cavity 9.

The fixed portion 6f is embedded in the insulating layer 3 with one surface (i.e., the upper surface in FIG. 1A) in contact with the piezoelectric layer 4. That is, one surface of the fixed portion 6f is in contact with the piezoelectric layer 4, and the remaining surfaces are surrounded by the insulating layer 3. The first excitation electrode 5 and the second excitation electrode 6 may be referred to as the upper electrode 5 and the lower electrode 6, and the upper excitation electrode 5 and the lower excitation electrode 6, respectively.

FIG. 4A is a trace drawing of a cross-sectional photograph of the first excitation electrode 5. As shown in FIG. 4A, the first excitation electrode 5 can be a laminated film. The laminated film of the first excitation electrode 6 can include metal layers and can optionally include dielectric layer(s). The addition of the optional dielectric layer(s) can improve the temperature characteristics of the elastic wave device 1. In the present example embodiment, the first excitation electrode 5 includes at least a first layer 5a and a second layer 5b. The first layer 5a and the second layer 5b are arranged in this order from the side of the piezoelectric layer 4. That is, the first layer 5a is closer to the piezoelectric layer 4 than the second layer 5b, and in FIG. 4A, the second layer 5b is above the first layer 5a. A dielectric layer can be included between the first layer 5a and the second layer 5b and/or a dielectric layer can be included between the first layer 5a and the piezoelectric layer 5b.

In the present example embodiment, the first layer 5a is thinner than the second layer 5b. For example, the thickness of the first layer 5a is in the range of about 10 nm to about 60 nm, within manufacturing and/or measurement tolerances. A resonator using a thickness longitudinal vibration mode of a Y-cut 36° RY lithium niobate substrate as the piezoelectric layer 4 can provide a resonance frequency of, for example, approximately 3.5 GHz, within manufacturing and/or measurement tolerances. The thickness of the second layer 5b is, for example, in the range of about 50 nm to about 200 nm, within manufacturing and/or measurement tolerances. The film thickness of the first layer 5a and the second layer 5b can be appropriately changed depending on the resonance frequency, vibration mode, and material of the piezoelectric layer 4.

The first layer 5a can include, for example, a metal or alloy having a density higher than that of the second layer 5b. The material of the first layer 5a can be selected from, for example, Pt, W, Mo, Ta, Au, Cu, or alloys of these metals. In the present example embodiment, for example, the first layer 5a includes Pt.

The second layer 5b can include, for example, a metal or alloy having a lower electrical resistance than the first layer 5a. The material of the second layer 5b can be, for example, Al, an alloy of Al, Cu, or an alloy of Cu. In the present example embodiment, for example, the second layer 5b includes an alloy of Al and Cu. Any member of the elastic wave device 1 can include a certain material, including a trace amount of an impurity which does not greatly deteriorate the electrical characteristics of the elastic wave device 1.

The first excitation electrode 5 may further include an adhesion layer 5x between the piezoelectric layer 4 and the first layer 5a. The adhesion layer 5x is thinner than the first layer 5a and the second layer 5b. The thickness of the adhesion layer 5x is, for example, between about 2 nm and about 20 nm, within manufacturing and/or measurement tolerances. The material of the adhesion layer 5x can be selected from, for example, Ti, Cr, or an alloy of these metals. An example alloy is NiCr. In the present example embodiment, the adhesion layer 5x includes Ti, for example.

The first excitation electrode 5 may further include an adhesion layer 5ab between the first layer 5a and the second layer 5b. The adhesion layer 5ab is thinner than the first layer 5a and the second layer 5b. The thickness of the adhesion layer 5ab can be, for example, between about 2 nm and about 20 nm, within manufacturing and/or measurement tolerances. The material of the adhesion layer 5ab can be selected from the group including Ti, Cr, and alloys of these metals. Examples of alloys include NiCr. In the present example embodiment, for example, the adhesion layer 5ab includes Ti. The first excitation electrode 5 may further include a protective layer 5bc on the second layer 5b. The protective layer 5bc is thinner than the first layer 5a and the second layer 5b. The thickness of the protective layer 5bc is, for example, between about 2 nm and about 20 nm, within manufacturing and/or measurement tolerances. The material of the protective layer 5bc can be selected from the group including, Ti, Cr, or alloys of these metals. An example alloys is NiCr. In the present example embodiment, the protective layer 5bc includes Ti, for example.

That is, the first excitation electrode 5 of the present example embodiment is a laminated film including the adhesion layer 5x, the first layer 5a, the adhesion layer 5ab, the second layer 5b, and the protective layer 5bc. The adhesion layer 5x, the first layer 5a, the adhesion layer 5ab, the second layer 5b, and the protective layer 5bc are arranged in this order from the piezoelectric layer 4 (i.e., the first main surface 4a of the piezoelectric layer 4). The first excitation electrode 5 may not be a laminated metal film, may be a single layer film including only the first layer 5a, or may be a single layer film including only the second layer 5b.

As shown in FIG. 1B, the elastic wave device 1 may include two types of resonators which are a series resonator S1 and a parallel resonator P1. In the case of a ladder filter, the frequency of the series resonator S1 is higher than the frequency of the parallel resonator P1, and in the present example embodiment, the thickness of the first excitation electrode 5 of the series resonator S1 is smaller than the thickness of the first excitation electrode 5 of the parallel resonator P1. As shown in FIG. 1A, the first excitation electrode 5 of the series resonator S1 may not be integrally provided with the first excitation electrode 5 of the parallel resonator P1. That is, the first excitation electrode 5 of the series resonator S1 may not be physically connected to the first excitation electrode 5 of the parallel resonator P1. But as shown in FIG. 1A, the first excitation electrode 5 of the series resonator S1 and the first excitation electrode 5 of the parallel resonator P1 can be connected by the first wiring electrode 7.

FIG. 4B is a trace drawing of a cross-sectional photograph of the second excitation electrode 6. As shown in FIG. 4B, the second excitation electrode 6 can be a laminated film. The laminated film of the second excitation electrode 6 can include metal layers and can optionally include dielectric layer(s). The addition of the optional dielectric layer(s) can improve the temperature characteristics of the elastic wave device 1. In the present example embodiment, the second excitation electrode 6 includes at least a first layer 6a and a second layer 6b. The first layer 6a is closer to the piezoelectric layer 4 than the second layer 6b, and in FIG. 4B, the second layer 6b is below the first layer 6a. A dielectric layer can be included between the first layer 6a and the second layer 6b and/or a dielectric layer can be included between the first layer 6a and the piezoelectric layer 6b.

In the present example embodiment, the first layer 6a is thinner than the second layer 6b. For example, the thickness of the first layer 6a is, for example, in the range of about 10 nm and about 60 nm, within manufacturing and/or measurement tolerances. For example, the thickness of the second layer 6b is in the range of about 50 nm to about 200 nm, within manufacturing and/or measurement tolerances.

The first layer 6a can include a metal or alloy having a density higher than that of the second layer 6b. The material of the first layer 6a can be selected from, for example, Pt, W, Mo, Ta, Au, Cu, or alloys of these metals. In the present example embodiment, the first layer 6a includes Pt, for example.

The second layer 6b can include a metal or alloy having a lower electrical resistance than the first layer 6a. The material of the second layer 6b can be, for example, Al, an alloy of Al, Cu, or an alloy of Cu. In the present example embodiment, the second layer 6b includes an alloy of Al and Cu, for example.

The first excitation electrode 6 may further include an adhesion layer 6x between the piezoelectric layer 4 and the first layer 6a. The adhesion layer 6x is thinner than the first layer 6a and the second layer 6b. The thickness of the adhesion layer 6x is, for example, between about 2 nm and about 20 nm, within manufacturing and/or measurement tolerances. The material of the adhesion layer 6x may be a metal such as, for example, Ti, Cr, or an alloy thereof. An example alloy is NiCr. In the present example embodiment, the adhesion layer 6x includes Ti, for example.

The first excitation electrode 6 may further include an adhesion layer 6ab between the first layer 6a and the second layer 6b. The adhesion layer 6ab is thinner than the first layer 6a and the second layer 6b. The thickness of the adhesion layer 6ab is, for example, between about 2 nm and about 20 nm, within manufacturing and/or measurement tolerances. The material of the adhesion layer 6ab may be a metal such as, for example, Ti, Cr, or an alloy thereof. An example alloy is NiCr. In the present example embodiment, the adhesion layer 6ab includes Ti, for example. The first excitation electrode 6 may further include a protective layer 6bc on the second layer 6b. The protective layer 6bc is thinner than the first layer 6a and the second layer 6b. The thickness of the protective layer 6bc is, for example, between about 2 nm and about 20 nm, within manufacturing and/or measurement tolerances. The material of the protective layer 6bc includes a metal or alloy such as, for example, Ti, NiCr, Cr, etc. In the present example embodiment, the protective layer 6bc includes Ti, for example.

That is, the first excitation electrode 6 of the present example embodiment is a laminated film of the adhesion layer 6x, the first layer 6a, the adhesion layer 6ab, the second layer 6b, and the protection layer 6bc. The adhesion layer 6x, the first layer 6a, the adhesion layer 6ab, the second layer 6b, and the protection layer 6bc are arranged in this order from the piezoelectric layer 4 (i.e., the second main surface 4b). The second excitation electrode 6 may not be a laminated metal film but may be a single layer film including only the first layer 6a or a single layer film including only the second layer 6b.

As shown in FIG. 1A, the elastic wave device 1 includes a first dielectric layer 61 covering the first excitation electrode 5. When the elastic wave device 1 includes a first frame 10 described later, the first dielectric layer 61 may cover the first frame 10. Further, the first dielectric layer 61 may be larger than the cavity 9 and overlap the cavity 9. The material of the first dielectric layer 61 can be any suitable dielectric material, such as, for example, silicon oxide, tantalum pentoxide, silicon nitride, aluminum nitride, etc. The first dielectric layer 61 of the present example embodiment includes silicon oxide, for example.

Although not shown in drawings, the elastic wave device 1 may further include a second dielectric layer covering the second excitation electrode 6. When the elastic wave device 1 includes a first frame 10 on the second excitation electrode 6, the second dielectric layer may cover the first frame 10. The material of the second dielectric layer can be any suitable dielectric material, such as, for example, silicon oxide, tantalum pentoxide, silicon nitride, aluminum nitride, etc.

The thicknesses of the first dielectric layer 61 and the second dielectric layer can be any suitable thickness in the excitation region and can be adjusted depending on the resonance frequency, vibration mode, and material of the piezoelectric layer 4.

As shown in FIG. 1A, the first wiring electrode 7 is provided on the fixing portion 5f of the first excitation electrode 5. The first wiring electrode 7 is not provided on the open portion 5e of the first excitation electrode 5. That is, the first wiring electrode 7 does not overlap the cavity 9 and is located outside the cavity 9.

The second wiring electrode 8 is provided under the fixed portion 6f of the second excitation electrode 6. The second wiring electrode 8 is not provided under the open portion 6e of the second excitation electrode 6. That is, the second wiring electrode 8 does not overlap the cavity 9 and is located outside the cavity 9.

Since the first wiring electrode 7 and the second wiring electrode 8 do not overlap the cavity 9, the difference in stress between the portion overlapping the cavity 9 and the portion not overlapping the cavity 9 in plan view in the elastic wave device 1 can be reduced. As a result, the stress applied to the elastic wave device 1 can be reduced as a whole.

In the present example embodiment, the first wiring electrode 7 and the second wiring electrode 8 can include a laminated metal film. As shown in FIGS. 1F and 1G, the first wiring electrode 7 can include a first layer 7a and a second layer 7b. The first layer 7a and the second layer 7b can be laminated in this order from the piezoelectric layer 4. In the present example embodiment, for example, the first layer 7a includes Ti, and the second layer 7b includes Al or an alloy of Al.

The second wiring electrode 8 can include a first layer 8a and a second layer 8b. The first layer 8a and the second layer 8b are laminated in this order from the piezoelectric layer 4. In the present example embodiment, the first layer 8a includes Ti. The second layer 8b includes Al or an alloy of Al.

The material of each layer of the first wiring electrode 7 and the second wiring electrode 8 is not limited to the above, and may be, for example, a metal or alloy including at least one of Al, Au, Cu, Cr, Ru, W, Mo, or Pt. The number of layers of the first wiring electrode 7 and the second wiring electrode 8 is not limited to two layers, and may be three or more layers, for example. Alternatively, the first wiring electrode 7 and the second wiring electrode 8 may include a single-layer metal film.

The first wiring electrode 7 and the second wiring electrode 8 may be referred to as the upper two-layer wiring 7 and the lower two-layer wiring 8, respectively.

The first wiring electrode 7 is electrically connected to other elements. In the present example embodiment, the first wiring electrode 7 is directly connected to a conductive wall 51 that is electrically connected to the bump 55, which provides an external terminal.

As shown in FIGS. 1A and 1C, the second wiring electrode 8 is embedded in the insulating layer 3. FIGS. 1A and 1C show a cross-sectional view of the second wring electrode 8 with four cross-sectional surfaces. One cross-sectional surface of the second wiring electrode 8 (the upper cross-sectional surface in FIGS. 1A and 1C) is surrounded by the second excitation electrode 6, and the remaining three cross-sectional surfaces are surrounded by the insulating layer 3. In other words, the second wiring electrode 8 can be embedded within the insulating layer 3 such that one surface of the second wiring electrode 8 contacts the second excitation electrode 6 and the other surfaces of the second wiring electrode 8 contact the insulating layer 3. The insulating layer 3 may extend to the second main surface 4b of piezoelectric layer 4 so as to cover at least a portion of the second excitation electrode 6 and the second wiring electrode 8.

The thickness of the first wiring electrode 7 can be thicker than the respective thicknesses of the first excitation electrode 5 and the second excitation electrode 6. The thickness of the second wiring electrode 8 can be thicker than the respective thicknesses of the first excitation electrode 5 and the second excitation electrode 6. Thus, the electrical resistance of the first wiring electrode 7 and the second wiring electrode 8 can be lowered.

When excitation regions A are located adjacent to each other, the second wiring electrode 8 can connect two second excitation electrodes 6 of the adjacent excitation regions A. By connecting the two second excitation electrodes 6 with a second wiring electrode 8 which is not integrated to the two second excitation electrodes 6, the leakage of waves between adjacent excitation regions A can be reduced or prevented. In this case, the second wiring electrode 8 can be thicker than the two second excitation electrodes 6. Thus, the excitation regions A adjacent to each other can be connected by the second wiring electrode 8 having lower electrical resistance.

As shown in FIGS. 1A and 1C, the thickness of the first wiring electrode 7 can be thicker than that of the second wiring electrode 8. As a result, the electrical resistance of the first wiring electrode 7 connected to the conductive wall 51 and bump 55, which defines the external terminal, can be lowered, and the heat dissipation of the elastic wave device 1 can be improved.

The total area of the first excitation electrode 5 and the first wiring electrode 7 can be larger than the total area of the second excitation electrode 6 and the second wiring electrode 8. Thus, heat dissipation of the elastic wave device 1 can be improved.

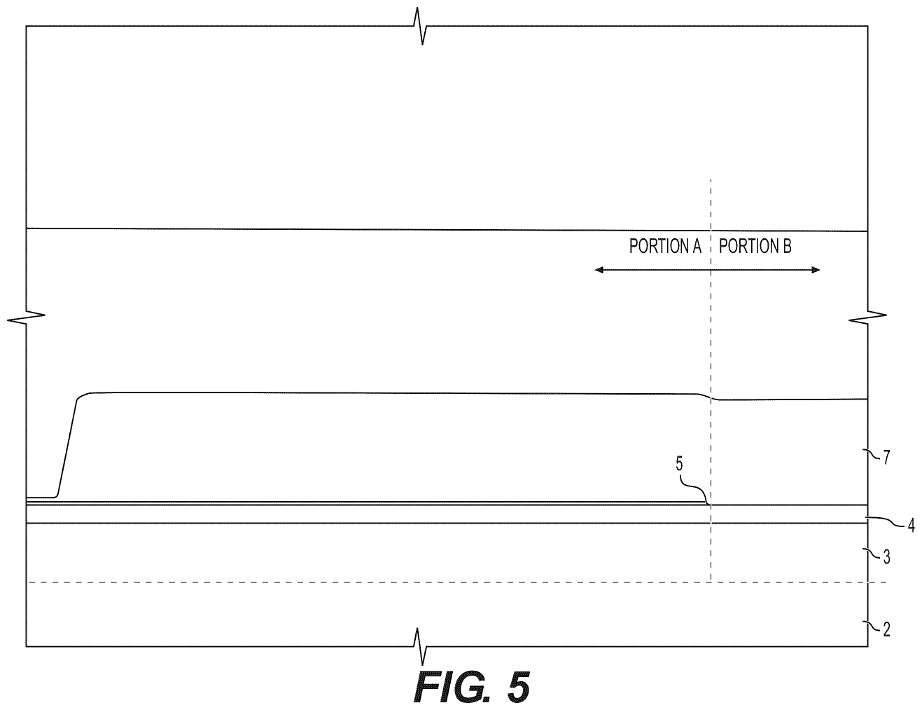

FIG. 5 is a trace drawing of an enlarged photograph of a cross section of the first wiring electrode 7 including a first region in which the first wiring electrode covers the first excitation electrode 5 (portion A) and a second region in which the first wiring electrode does not cover the first excitation electrode 5 (portion B). As shown in FIG. 5, a step is included in the first wiring electrode 7. The first wiring electrode 7 covers the end of the first excitation electrode 5. That is, the level difference caused by the presence or absence of the first excitation electrode 5 is covered by the first wiring electrode 7. The level difference is caused in the first wiring electrode 7. The position where the step is generated is the boundary between the portions A and B shown in FIG. 1A.

As described above, the thickness of the first excitation electrode 5 may differ between the series resonator S1 and the parallel resonator P1. If the first excitation electrode 5 extends to the sealing region of the elastic wave device 1 and if the first wiring electrode 7 having the same or substantially the same thickness is located on the first excitation electrode 5 of the series resonator S1 and on the first excitation electrode 5 of the parallel resonator P1, when the elastic wave device 1 is sealed using the first wiring electrode 7, the total thickness of the first excitation electrode 5 and the first wiring electrode 7 differs in the sealing region between the portion where the first excitation electrode 5 of the series resonator S1 is located and the portion where the first excitation electrode 5 of the parallel resonator P1 is located. Therefore, the first wiring electrode 7 does not have to be located under the first excitation electrode 5 at least in the sealing region. The first wiring electrode 7 includes a step difference between a portion (portion A) where the first excitation electrode 5 is located and a another portion (portion B) where the first excitation electrode 5 is not located.

As described above, as shown in FIG. 1A, the first wiring electrode 7 may be located across the series resonator S1 and the parallel resonator P1. As described above, the thickness of the first excitation electrode 5 of the series resonator S1 and the first excitation electrode 5 of the parallel resonator P1 may be different from each other. In this case, a step is included in the first wiring electrode 7 located across the series resonator S1 and the parallel resonator P1. If the first excitation electrode 5 of the series resonator S1 is not physically connected to the first excitation electrode 5 of the parallel resonator P1 (i.e., when the first excitation electrode 5 is divided into separate portions), the first wiring electrode 7 can include a step caused by the break in the first excitation electrode 5.

The elastic wave device 1 can include one or more frames that can be used to change sound velocity. For example, a frame can surround the excitation region A such that sound velocity at the periphery of the excitation region A is different than the sound velocity in the interior of the excitation region A, which can reduce or prevent unwanted standing waves. The frame can be located on top of the excitation electrode, e.g., either the first excitation electrode 5 or the second excitation electrode 6, or can be located under the excitation electrode. If the frame is located under the excitation electrode, then a portion of the frame can extend beyond the end of the excitation electrode. If the frame extends beyond the end of the excitation electrode, then it is easy to observe the workmanship such as the positional deviation of the frame, making it is possible to reduce the number of defective products.

In the example embodiment of FIG. 1A, the elastic wave device 1 includes a first frame 10 and a second frame 11 along the excitation region A. The first frame 10 and the second frame 11 are arranged to confine excitation energy generated in the excitation region A and to reduce or prevent unnecessary standing waves. Each of the first frame 10 and the second frame 11 can extend around the entire excitation region A or can extend around only a portion of the excitation region. Each the first frame 10 and the second frame 11 can be a single continuous element or can be two or more discrete elements. The first frame 10 and the second frame 11 can have the same or substantially the same shape, within manufacturing and/or measurement tolerances, or can have different shapes. For example, the first frame 10 can have a circular or elliptical shape in which the first frame 10 extends around the entire excitation region A, and the second frame 11 can be semi-circular or can be an arc of an elliptical shape in which the second frame 11 extends around only a portion of the excitation region A.

In the present example embodiment, the first frame 10 and the second frame 11 are provided on the side of the piezoelectric layer 4 with the first excitation electrode 5. For example, the first frame 10 is provided on the first excitation electrode 5, and the second frame 11 is provided between the first excitation electrode 5 and the piezoelectric layer 4. In other words, the second frame 11 is provided on the first main surface 4a of the piezoelectric layer 4.

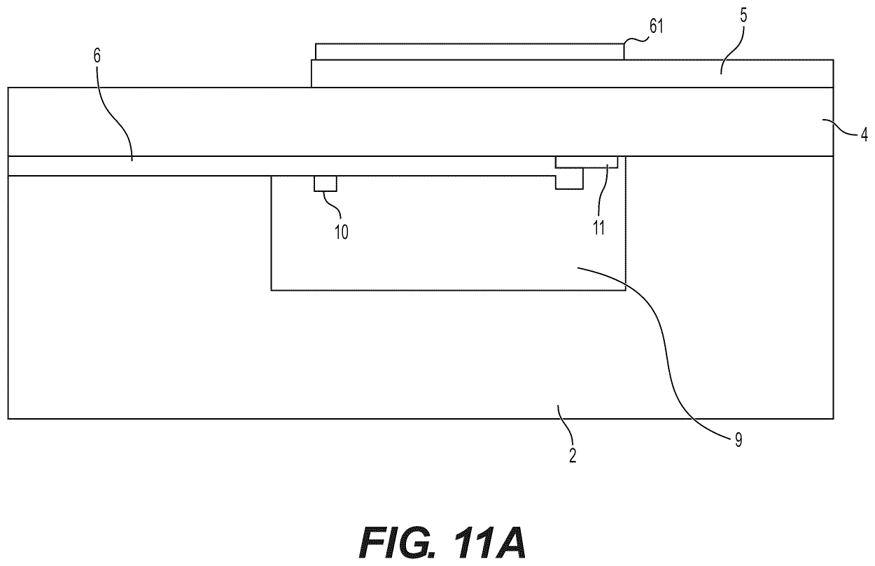

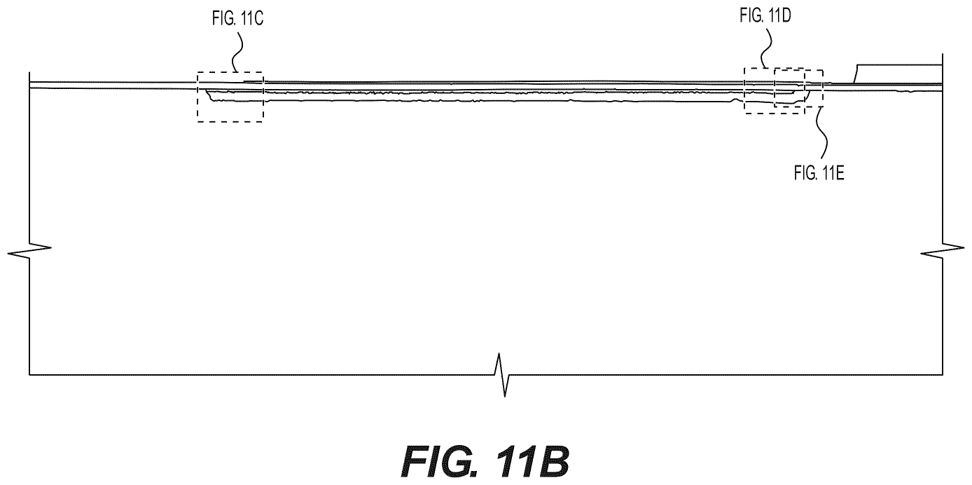

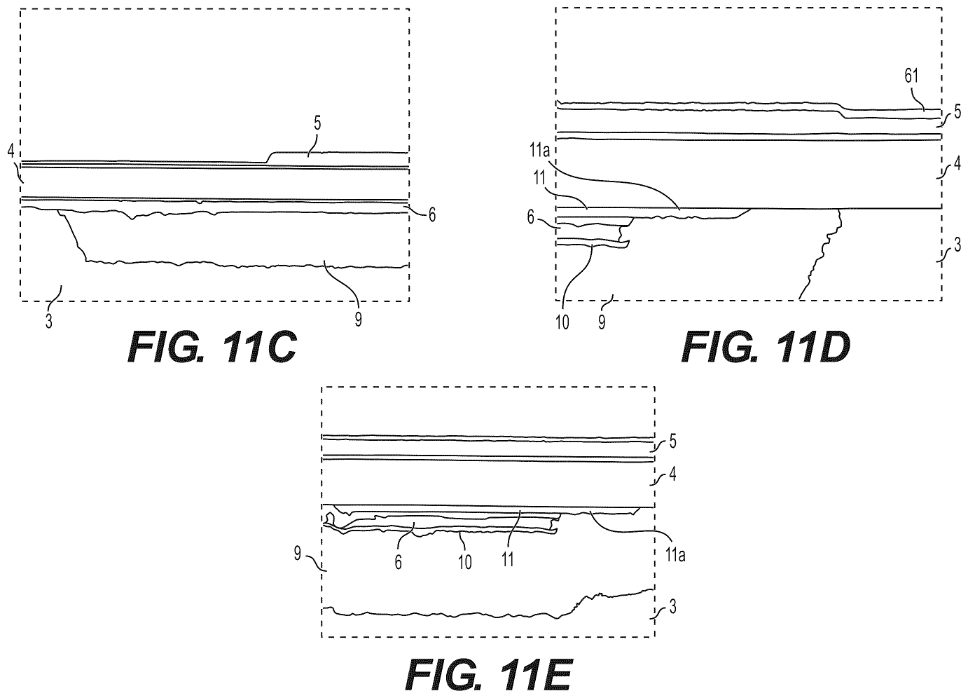

Alternatively, as shown in FIG. 11A-11E, the first frame 10 and the second frame 11 may be provided on the side of the piezoelectric layer 4 with the second excitation electrode 6. That is, the elastic wave device 1 may include a first frame 10 provided on the second excitation electrode 6 and/or a second frame 11 provided between the second excitation electrode 6 and the piezoelectric layer 4. In other words, the elastic wave device 1 may include a second frame 11 provided on the second main surface 4b of the piezoelectric layer 4. Including the first frame 10 and the second frame 11 on the second excitation electrode 5 without a dielectric layer over the first and second frames 10 and 11 can reduce losses because the first frame 10 and the second frame 11 can more efficiently confine excitation energy in the excitation region A and reduce or prevent unnecessary standing waves. If the first frame 10 and/or the second frame 11 is on the second excitation electrode 5, then the end of the second excitation electrode 5 can include a recess, which is shown in FIG. 11E.

The elastic wave device 1 need not necessarily include both of the first frame 10 and the second frame 11. The elastic wave device 1 may include only a first frame 10 or only a second frame 11. Even if only one of the first frame 10 or the second frame 11 is used, the excitation energy generated in the excitation region A can be confined, and unnecessary standing waves can be reduced or prevented.

When the second frame 11 is provided on the first main surface 4a of the piezoelectric layer 4, the first excitation electrode 5 may be provided on the second frame 11. When the first excitation electrode 5 is provided on the second frame 11, the portion of the first excitation electrode 5 on the second frame 11 is raised by the second frame 11 in comparison with other portions of the first excitation electrode 5 that are not on the second frame 11. A structure including a lifted first excitation electrode 5 is also referred to as a cantilever structure. The cantilever structure may be defined by a second frame 11. Alternatively, for example, a cantilever structure may be defined by forming a portion corresponding to the second frame 11 with zinc oxide or magnesium oxide, forming a first excitation electrode 5, and then melting the zinc oxide or to magnesium oxide with a chemical solution, forming a cavity or space between the cantilever structure of the first excitation electrode 5 and the piezoelectric layer 4.

The first frame 10 and the second frame 11 may have a band-shape, for example. The first frame 10 may have partially different widths and the second frame 11 may have partially different widths. Each of the first frame 10 and the second frame 11 may include a narrow portion and a wide portion periodically. A jagged frame refers to a frame that include periodic or alternating narrow and wide portions. On the other hand, a normal frame refers to a frame with a constant width, i.e., without periodic narrow and wide portions. In a jagged frame, because the frame width is not constant, the effect of an unnecessary wave outside of a target band can be reduced, and the effect of an unnecessary ripple wave inside a target band can also be reduced. The same process that is used to make a normal frame can be used to make a jagged frame because the thickness of a jagged frame is not changed.

The first frame 10 and the second frame 11 may be provided along all of the excitation region A or only a portion of the excitation region A. For example, the first frame 10 and the second frame 11 may be located only along the first wiring electrode 7 (and/or the second wiring electrode 8) in the excitation region A. For example, when the excitation region A is circular or substantially circular, the first frame 10 and the second frame 11 may be circular or substantially circular depending on the shape of the excitation region A. For example, in the case where the excitation region A is rectangular or substantially rectangular, the first frame 10 and the second frame 11 may be rectangular or substantially rectangular frames or may have a shape in which at least one side of the rectangular or substantially rectangular frame is missing. For example, in the case where the excitation region A is elliptical or substantially elliptical, the first frame 10 and the second frame 11 may be elliptical or substantially elliptical frames or may be circular or substantially circular arcs of elliptical frames. For example, in the case where the excitation region A is a polygon, the first frame 10 and the second frame 11 may be a polygonal frame, and at least one side of the polygonal frame may be missing.

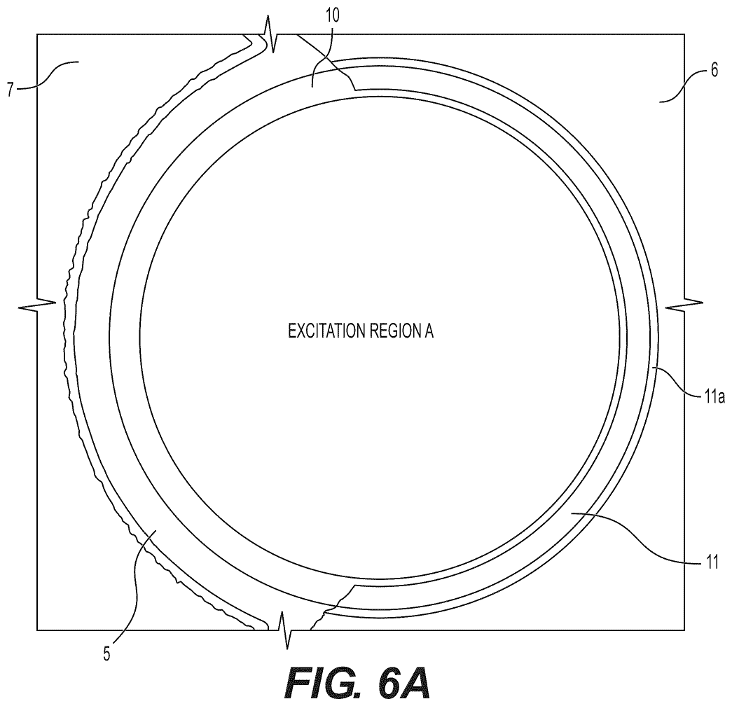

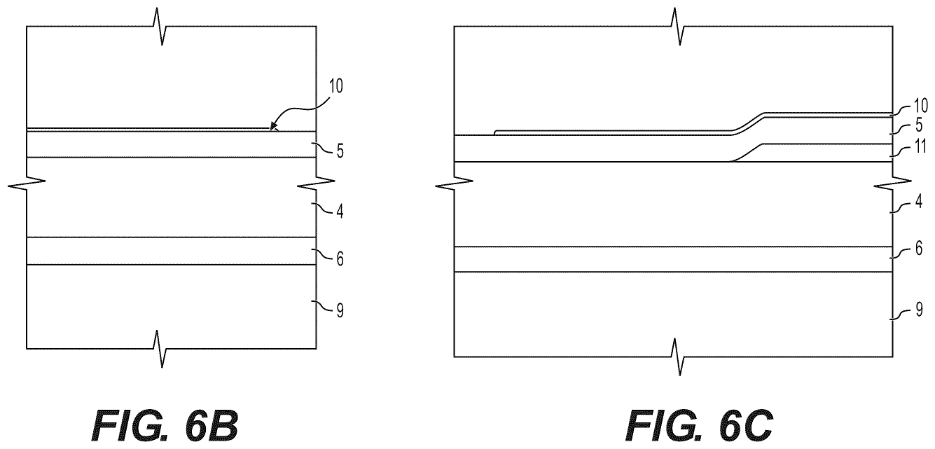

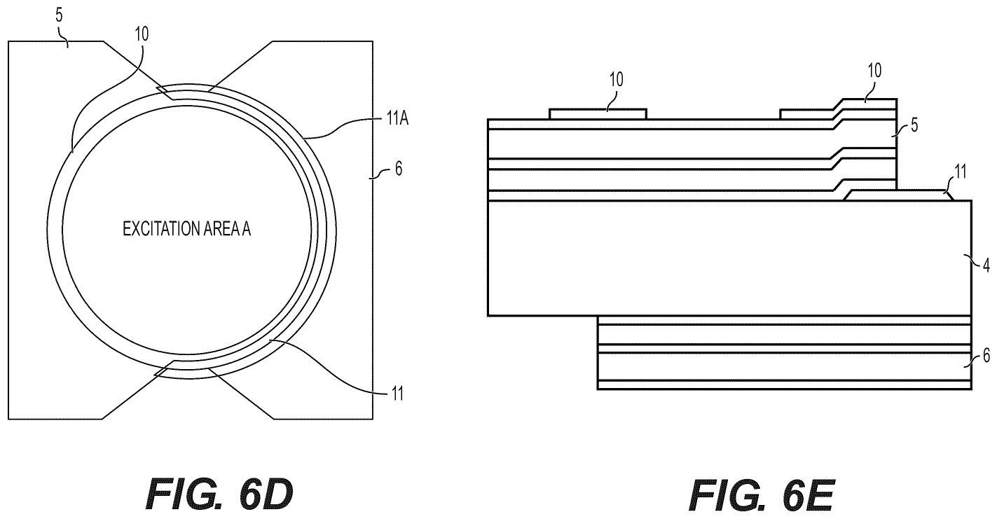

FIGS. 6A-6E show a first frame 10 and a second frame 11. FIG. 6A is a trace drawing of a plan view photograph of an excitation region A. FIGS. 6B and 6C are trace drawings of cross-sectional photographs showing the first frame 10 and the second frame 11 of FIG. 6A. FIG. 6D is a plan-view schematic drawing of the excitation region A of FIG. 6A. FIG. 6E is a cross-sectional schematic drawing of the first frame 10 and the second frame 11 of FIG. 6D. As shown in FIGS. 6A-6E, when the elastic wave device 1 includes both of the first frame 10 and the second frame 11, the first frame 10 may be provided all around the excitation region A, and the second frame 11 may be provided along a portion of the excitation region A. For example, the second frame 11 can extend around roughly half of the perimeter of the excitation region A. In order to connect the excitation region A to another excitation region or an external terminal, the excitation electrode 5 can extend from the excitation region A to define a wiring portion of the excitation electrode 5. Similarly, in order to connect the excitation region A to another excitation region or an external terminal, the excitation electrode 6 can extend from the excitation region A to define a wiring portion of the excitation electrode 6.

The first frame 10 can include a metal or a dielectric, for example. A frame including metal is a frame electrode 10. The metals used as materials for the first frame 10 include, for example, Pt, W, Mo, Ti, Al, Cu, or alloys thereof. The dielectric material of the first frame 10 includes, for example, silicon oxide, tantalum pentoxide, or silicon nitride.

The second frame 11 can include a dielectric. The dielectric material of the second frame 11 includes, for example, silicon oxide, tantalum pentoxide, or silicon nitride. The cantilever structure is referred to herein as a cantilever or a dielectric cantilever. If the second frame 11 includes silicon oxide, for example, then the cantilever or dielectric cantilever can be referred to as a SiO₂ cantilever. The second frame 11 can also be provided as a cavity or space, as explained above.

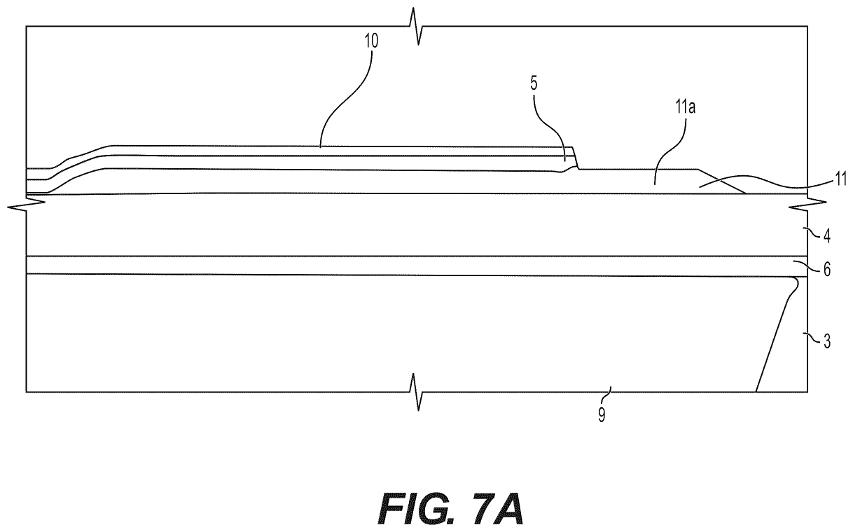

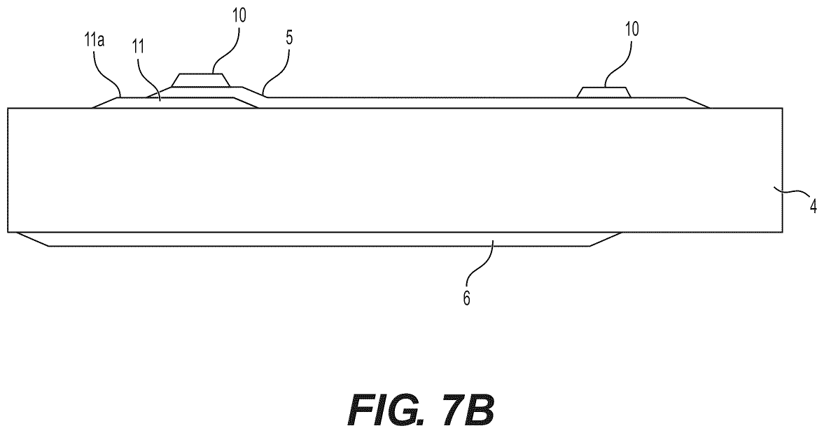

FIGS. 7A and 7B show the first frame 10, the first excitation electrode 5, and the second frame 11. FIG. 7 is a trace drawing of a cross-sectional photograph of the first frame 10, the first excitation electrode 6, and the second frame 11 within the excitation region A over the cavity 9. FIG. 7B is a cross-sectional schematic drawing of the first frame 10, the first excitation electrode 5, and the second frame 11. When the first frame 10 includes dielectric material, such as silicon oxide, for example, and is provided between the first excitation electrode 5 and the piezoelectric layer 4, the second frame 11 may include a dielectric cantilever 11a that extends past the end of the first excitation electrode 5 and may be exposed from or not covered by the first excitation electrode 5, as shown in FIGS. 7A and 7B. The end of the dielectric cantilever 11a can include, for example, a ramp or slope in which the thickness of dielectric cantilever 11a reduces toward the exposed end of the second frame 11. With this arrangement, by exposing the dielectric cantilever 11a of the second frame 11, the workmanship of the second frame 11 can be confirmed. The dielectric cantilever 11a of the second frame 11 is exposed and extends from the first excitation electrode 5, but the end of dielectric cantilever 11a of the second frame 11 is inside the perimeter of the cavity 9 when viewed in a plan view. That is, the second frame 11, including the dielectric cantilever 11a, is located in a region overlapping the cavity 9, when view in plan. As shown in FIGS. 11A-11E, when the second frame 11 includes a dielectric material, such as silicon oxide, for example, and is provided between the second excitation electrode 6 and the piezoelectric layer 4, the second frame 11 may include a dielectric cantilever 11a that extends past the end of the second excitation electrode 6 and may be exposed from or not covered by the second excitation electrode 6.

The first frame 10 and the second frame 11 can at least partially overlap. Further, the first frame 10 and the second frame 11 provided on the side of the piezoelectric layer 4 with the first excitation electrode 5 are located at positions overlapping with the second excitation electrode 6. The first frame 10 and the second frame 11 provided on the second excitation electrode 6 side of the piezoelectric layer 4 may be in a position overlapping with the first excitation electrode 5.

The shapes, materials, and arrangements of the first frame 10 and the second frame 11 described thus far can be combined. The characteristics of each combination are shown in Table 1 below.

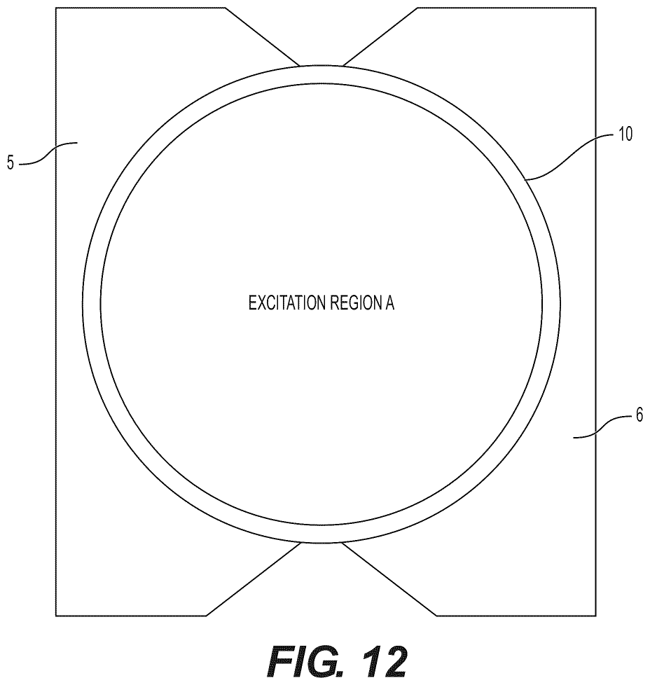

FIGS. 12-20 shows various configurations (i.e., Arrangements A-G) of the first frame 10 and the second frame 11. Table 1 compares the antiresonance characteristics, the reduction or prevention of low-frequency unwanted wave, and the displacement accuracy of the frame for different arrangements of the first frame 10 and the second frame 11. In Table 1, a score 1, 2, 3, or 4 is assigned to each the compared characteristics, with 1 being the best score and 4 being the worst score. The antiresonance characteristics can deteriorate if the frame is not properly located or if the thickness of the frame is thinner or thicker than desired.

FIG. 12 shows Arrangement A in which the first frame 10 is a normal frame that is located on the excitation electrode 5. The first frame 10 has a constant width over the entire or substantially the entire circumference of the excitation region A.

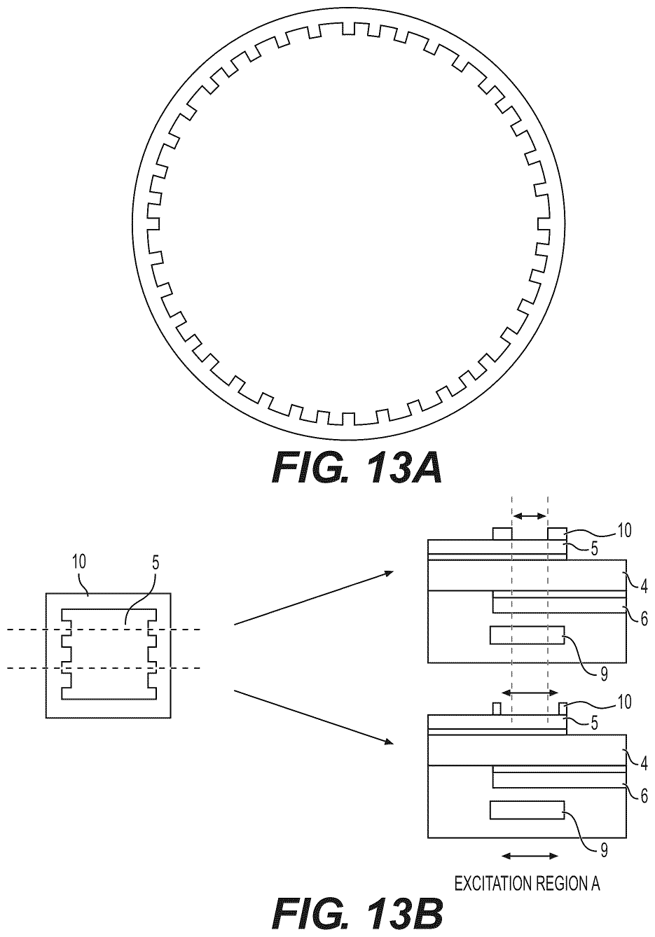

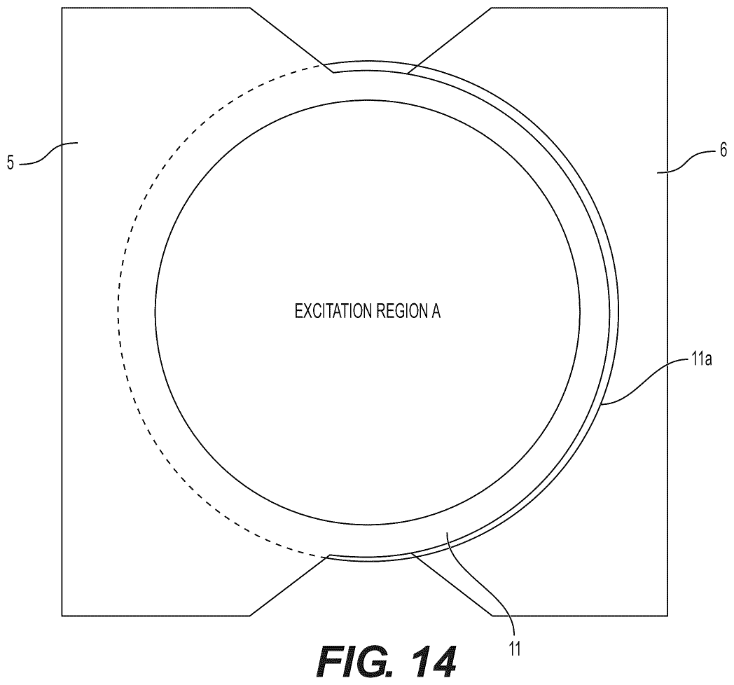

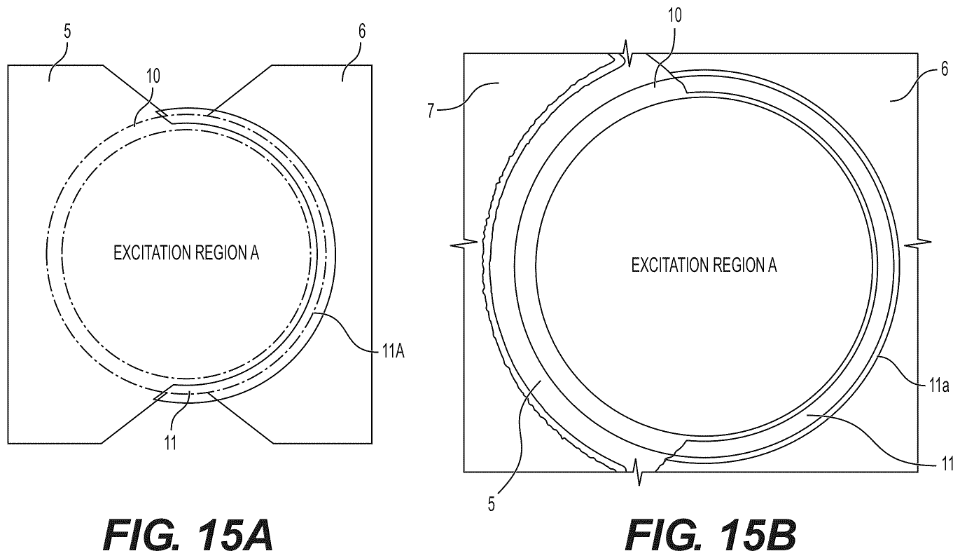

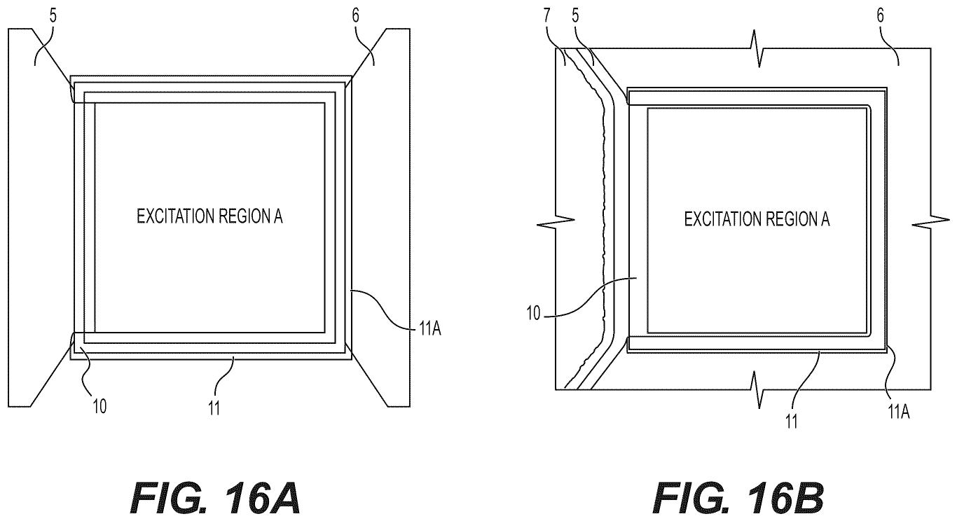

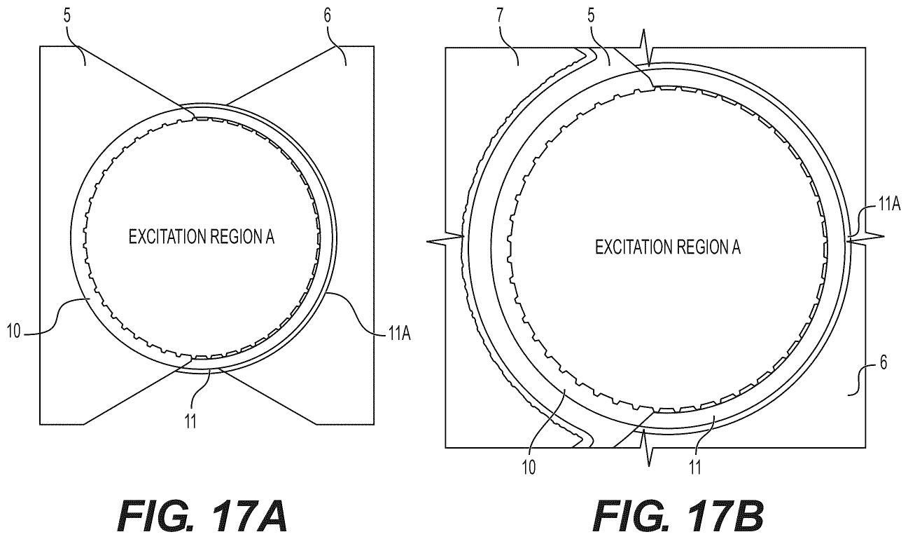

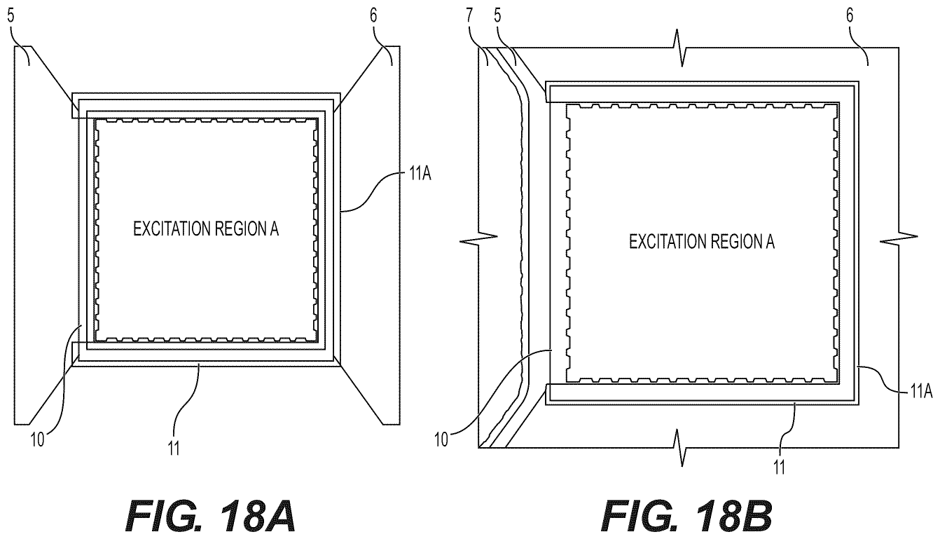

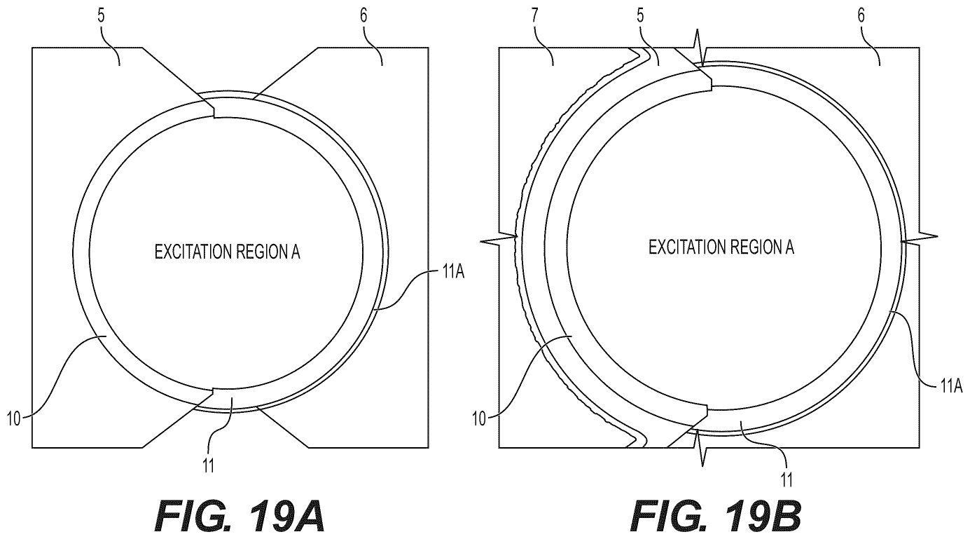

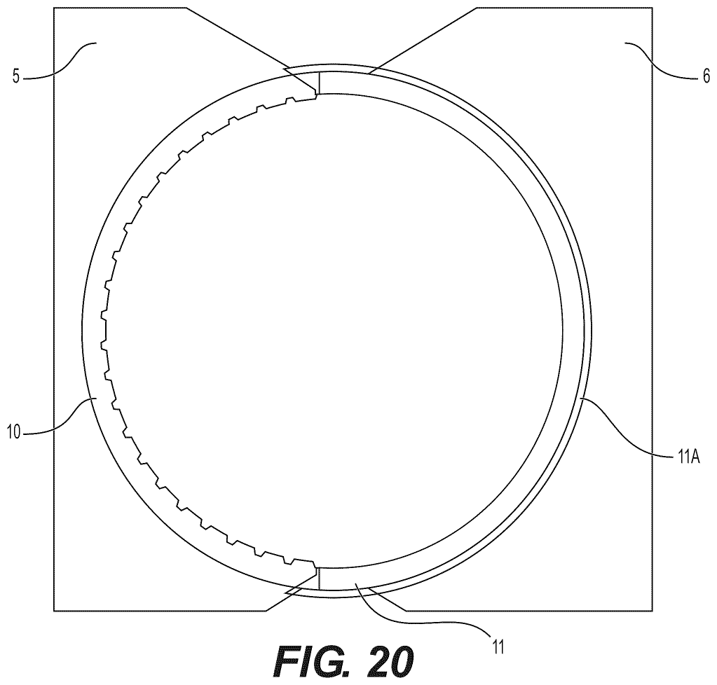

FIGS. 13A and 13B shows Arrangement B in which the first frame 10 is a jagged frame. The first frame 10 includes periodically arranged narrow portions and wide portions and extends around the entire or substantially the entire circumference of the excitation region A of the excitation electrode 5.

FIG. 14 shows Arrangement C in which the second frame includes a dielectric cantilever 11a and in which the second frame 11 has a constant width between the excitation electrode 5 and the piezoelectric layer 4 over the entire or substantially the entire circumference of the excitation region A of the excitation electrode 5.

FIGS. 15A-16B show Arrangement D in which the first frame 10 is a normal frame and the second frame includes a dielectric cantilever. The first frame 10 is located on the excitation electrode 5, has a constant width, and extends along the entire or substantially the entire circumference of the excitation region A. The second frame 11 has a constant width, is located between the excitation electrode 5 and the piezoelectric layer 4, and extends along the circumference of the excitation region A except along the wiring portion of the excitation electrode 5. In FIGS. 15A and 15B, the excitation region A is circular, and in FIGS. 16A and 16B, the excitation region A is rectangular.

FIGS. 17A-18B show Arrangement E in which the first frame 10 is a jagged frame and the second frame 11 includes a dielectric cantilever 11a. The first frame 10 includes periodically arranged narrow portions and wide portions, extends along the entire or substantially the entire circumference of the excitation region A, and is located on the excitation electrode 5. The second frame 11 has a constant width, is located between the excitation electrode 5 and the piezoelectric layer 4, and extends along the circumference of the excitation region A except along the wiring portion of the excitation electrode 5. In FIGS. 17A and 17B, the excitation region A is circular, and in FIGS. 18A and 18B, the excitation region A is rectangular.

FIGS. 19A and 19B show Arrangement F in which the first frame 10 is a normal frame and the second frame 11 is a dielectric cantilever 11a. The first frame 10 has a constant width and extends along the circumference of the excitation region A only along the wiring portion of the excitation electrode 5. The second frame 11 has a constant width, is located between the excitation electrode 5 and the piezoelectric layer 4, and extends along the circumference of the excitation region A except along the wiring portion of the excitation electrode 5.

FIG. 20 shows Arrangement G in which the first frame 10 is a jagged frame and the second frame 11 includes a dielectric cantilever. The first frame 10 includes periodically arranged narrow portions and wide portions and extends along the circumference of the excitation region A only along the wiring portion of the excitation electrode 5. The second frame 11 has a constant width, is located between the excitation electrode 5 and the piezoelectric layer 4, and extends along the circumference of the excitation region A except along the wiring portion of the excitation electrode 5. In this specification, “constant width” includes manufacturing and/or measurement tolerances.

TABLE 1

| | A | B | C | D | E | F | G |
|---|---|---|---|---|---|---|---|
| Anti-resonance characteristics | 1 | 3 | 4 | 1 | 3 | 2 | 3 |
| Low frequency unwanted wave | 4 | 3 | 1 | 4 | 3 | 2 | 2 |
| Displacement accuracy of frame | 4 | 4 | 1 | 3 | 3 | 2 | 2 |

In addition, the combination of the shape, material, and arrangement of the first frame 10 and the second frame 11, and the combination of the appropriate frequency band and arrangement method of the elements are shown in Table 2 below.

Table 2 compares the characteristics of a series resonator and a parallel resonator in a ladder filter, and assigns a score of 1, 2, or 3, where 1 is the best score and 3 is the worst score. In a ladder filter circuit, a series resonator is usually used to provide a high pass through a filter region, and a parallel resonator is usually used to provide a low pass through the filter region.

When the anti-resonance characteristic of the series resonator is good, the high range steepness of the filter band is improved, and the filter characteristic is improved. When a low-pass unwanted wave is generated in the series resonator and the unwanted wave exists in the passband, ripple occurs in the passband, and filter performance is degraded. Further, when a low-frequency unwanted wave is generated in the series resonator and the unwanted wave exists in the band of another filter sharing the antenna, ripple generation into the band of the other filter and degradation of the attenuation region occurs, and the filter characteristics are degraded.

When the anti-resonance characteristic of the parallel resonator is good, the pass loss of the filter band is reduced and the filter characteristic is improved. In addition, when a low-frequency unwanted wave is generated in the parallel resonator and the unwanted wave exists in the band of the other filter sharing the antenna, ripple generation into the band of the other filter and degradation of the attenuation region occurs, thus degrading the filter characteristics.

In the table below, it is assumed that N77 and N79 are diplexers that share antennas. In this configuration, because the frequency of the pass region of the N77 is lower than that of the N79, the parallel resonator of the N77 does not affect the N79 sharing the antenna, even if unwanted waves are generated in the low region, and therefore, Arrangement D is the best because its anti-resonance characteristics are the best. On the other hand, when N77 and N79 are used in carrier aggregation (CA) with other bands, for example, when carrier aggregation is performed between N41 and N77, when N41 is in the low range of N77 and when a low-frequency unwanted wave is generated at a frequency that affects N41, Arrangement D is best, even in the N77 parallel resonator.

TABLE 2

| | C | D | E | F | G |
|---|---|---|---|---|---|
| N77 series | 2 | 3 | 3 | 1 | 1 |
| N77 parallel | 3 | 1 | 3 | 2 | 3 |
| N79 series | 2 | 3 | 3 | 1 | 1 |
| N79 parallel | 2 | 3 | 3 | 1 | 1 |

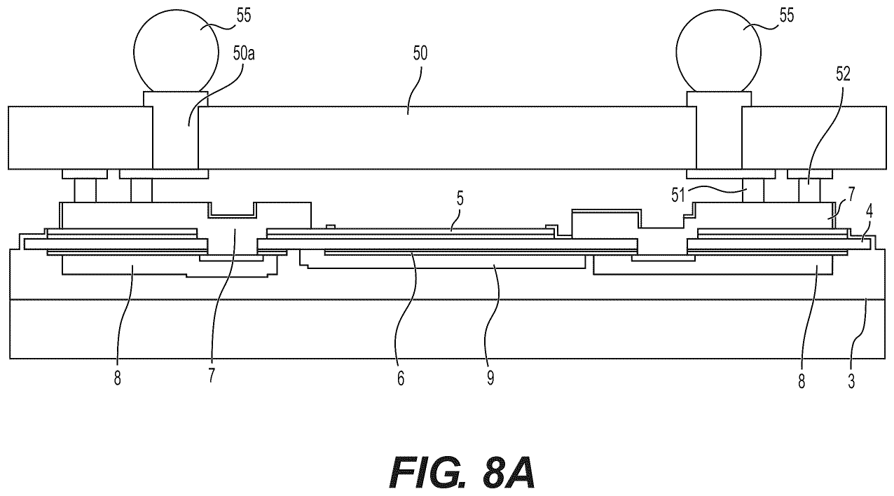

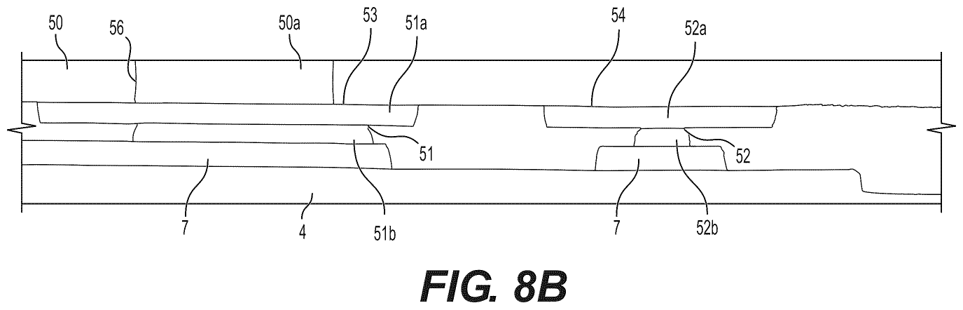

FIG. 8A is a cross-sectional schematic drawing of the structure of the elastic wave device. FIGS. 8B is a trace drawing of a cross-sectional photograph of the elastic wave device 1 and drawings for explaining the structure thereof. In the present example embodiment, as shown in FIGS. 8A and 8B, the elastic wave device 1 further includes a lid 50, a conductive wall 51, and a sealing frame 52. The conductive wall 51 is located on the lid 50 and is connected between bumps 55, which are external terminals, and the first wiring electrode 7. The conductive wall 51 can extend in a line such as a wiring. The sealing frame 52 surrounds the resonators and connects the lid 50 and the support substrate 2. That is, the sealing frame 52 defines a sealing structure together with the lid 50 and the support substrate 2. In the present example embodiment, the sealing frame 52 connects the lid 50 and the first wiring electrode 7 on the support substrate 2.

A via 50a is connected to the bump 55, which is an external terminal, on the lid 50. The conductive wall 51 connects the via 50a to the first wiring electrode 7. That is, the first wiring electrode 7 is connected to the external terminal via the conductive wall 51 and the via 50a. The conductive wall 51 is disposed inside the sealing frame 52. In other words, the conductive wall 51 is located within the sealing structure including the sealing frame 52. As shown in the plan view of the elastic wave device 1 in FIG. 1H, the conductive wall 51 may be connected to the sealing frame 52. In the present example embodiment, the external terminal includes a bump 55. The bump 55 is located on a surface of the lid 50 opposite to the surface facing the first wiring electrode 7. In the present example embodiment, the external terminal includes a solder bump, for example. The external terminal is not limited to solder bumps and may be, for example, Au bumps, or may be a land-shaped terminal (in which the external terminals are arranged in an LGA (Land Grid Array) provided by plating NiAu, or other suitable metal, on via 50a, for example. That is, the external terminal can have a shape other than a bump shape.

The material of the lid 50 may be, for example, silicon, aluminum oxide, alumina, quartz, sapphire, silicon nitride, silicon carbide, diamond, gallium nitride, or glass. The lid 50 includes, for example, a silicon substrate in the present example embodiment. The impact resistance and moisture resistance of the elastic wave device 1 can be improved by using a silicon substrate as a lid 50.

The via 50a includes a metal having low electrical resistance. In the present example embodiment, the via 50a includes copper, for example. A dielectric layer 56 may be disposed between the via 50a and the lid 50. The dielectric is, for example, silicon oxide or silicon nitride. In the present example embodiment, the dielectric layer 56 includes silicon oxide, for example. The via 50a extends perpendicular or substantially perpendicular within manufacturing and/or measurement tolerances to one surface of the lid 50.

The conductive wall 51 includes a first portion 51a and a second portion 51b. The first portion 51a and the second portion 51b are connected, and the first portion 51a is connected to the via 50a the lid 50. The second portion 51b connects the first portion 51a to the first wiring electrode 7.

The first portion 51a can include a laminated film. As shown in FIG. 1F, the first portion 51a includes a first layer 51aa, a second layer 51ab, a third layer 51ac, and a fourth layer 51ad in this order from the second portion 51b side (i.e., lower side of FIG. 1F).

The conductive wall 51 includes one or more metals. The material of the first layer 51aa can be, for example, Pt, W, Mo, Ta, Au, Cu, of alloys of these metals. In the present example embodiment, the first layer 51aa includes Au, for example.

The material of the second layer 51ab can be, for example, Pt, W, Mo, Ta, Au, Cu, or alloys of these metals. In the present example embodiment, the second layer 51ab includes Pt, for example.

The material of the third layer 51ac can be, for example, Cu, Al, and an alloy of these metals. In the present example embodiment, the third layer 51ac includes an alloy of Al, for example.

The material of the fourth layer 51ad can be, for example, Pt, W, Mo, Ta, Au, Cu, or alloys of these metals. In the present example embodiment, the fourth layer 51ad includes Pt, for example.

That is, for example, the layer closest to the second portion 51b of the first portion 51a (i.e., the first layer 51aa) includes Au. The first portion 51a includes a layer including Pt (i.e., the second layer 51ab) next to the layer including Au (i.e., the first layer 51aa).

The thickest of the first layer 51aa, the second layer 51ab, the third layer 51ac, and the fourth layer 51ad is a layer of Al or an alloy of Al, for example, the third layer 51ac.

The first portion 51a is not limited to a laminated structure, and may be a single layer film of only the first layer 51aa, or may be a laminated film of at least the first layer 51aa and the second layer 51ab. Other configurations are also possible.

The first portion 51a may be provided with an adhesion layer between the second layer 51ab and the third layer 51ac, and between the third layer 51ac and the fourth layer 51ad, respectively. In the present example embodiment, for example, the adhesion layer includes Ti, but it is not limited to Ti. For example, an alloy of Ti or Cr may be used. An example alloy of Cr is NiCr.

The second portion 51b can include a laminated film. As shown in FIG. 1F, the second portion 51b includes a first layer 51ba, a second layer 51bb, and a third layer 51bc in this order from the side of the first portion 51a (i.e., the upper side of FIG. 1F).

The material of the first layer 51ba can be, for example, Pt, W, Mo, Ta, Au, Cu, or alloys of these metals. In the present example embodiment, the first layer 51ba includes Au, for example.

The material of the second layer 51bb can be, for example, Pt, W, Mo, Ta, Au, Cu, or alloys of these metals. In the present example embodiment, the second layer 51bb includes Pt, for example.

The material of layer 51bc can be, for example, Cu, Al, or alloys of these metals. In the present example embodiment, the third layer 51ac includes an alloy of Al, for example.

That is, for example, the layer closest to the first portion 51a of the second portion 51b (that is, the first layer 51ba) includes Au. That is, for example, the first portion 51a and the second portion 51b each include a layer of Au and are connected to each other by the layer of Au. The second portion 51b includes, for example, a layer including Pt (i.e., the second layer 51bb) next to the layer of Au (i.e., the first layer 51ba).

The thickest of the first layer 51ba, the second layer 51bb, and the third layer 51bc can be a layer of Al or an alloy of Al, for example, the third layer 51bc.

The second portion 51b may include an adhesion layer between the second layer 51bb and the third layer 51bc. The adhesion layer can include Ti, for example.

The second portion 51b is not limited to a laminated structure and may be a single layer film of only the first layer 51ba, or may be a laminated film of the first layer 51ba and the second layer 51bb.

As shown in FIGS. 8A and 8B, the first portion 51a tapers toward the second portion 51b. That is, the first portion 51a has a tapered shape toward the second portion 51b. The second portion 51b and the first wiring electrode 7 become thinner toward the first portion 51a. That is, the second portion 51b and the first wiring electrode 7 have a tapered shape toward the first portion 51a. The tapered shape of the first portion 51a is opposite to that of the second portion 51b and the first wiring electrode 7.

A dielectric layer 53 may be located between the lid 50 and the conductive wall 51. In the present example embodiment, the dielectric layer 53 includes silicon oxide, for example. An adhesion layer may be located between the conductive wall 51 and the dielectric layer 53. In the present example embodiment, for example, the adhesion layer includes Ti, but it is not limited to Ti. For example, an alloy of Ti or Cr may be used. An example alloy of Cr is NiCr.

The sealing frame 52 can include metal. Thus, the moisture resistance of the elastic wave device 1 can be improved. The sealing frame 52 includes a first portion 52a and a second portion 52b. The first portion 52a connects the lid 50 and the second portion 52b. The second portion 52b connects the first portion 52a to the first wiring electrode 7.

The first portion 52a can be a laminated film. As shown in FIG. 1G, the first portion 52a includes a first layer 52aa, a second layer 52ab, a third layer 52ac, and a fourth layer 52ad in this order from the second portion 52b side (lower side of FIG. 1G).

The material of the first layer 52aa can be, for example, Pt, W, Mo, Ta, Au, Cu, or alloys of these metals. In the present example embodiment, the first layer 52aa includes Au, for example.

The material of the second layer 52ab can be, for example, Pt, W, Mo, Ta, Au, Cu, or alloys of these metals. In the present example embodiment, the second layer 52ab includes Pt, for example.

The material of the third layer 52ac can be, for example, Cu, Al, or alloys of these metals. In the present example embodiment, the third 51ac includes an alloy of Al, for example.

The material of the fourth layer 52ad can be, for example, Pt, W, Mo, Ta, Au, Cu, or alloys of these metals. In the present example embodiment, the fourth layer 52ad includes Pt, for example. That is, for example, the layer closest to the second portion 52b of the first portion 52a (that is, the first layer 52aa) includes Au. The first portion 52a includes a layer of Pt (i.e., the second layer 52ab) next to a layer of Au (i.e., the first layer 52aa).

The thickest of the first layer 52aa, the second layer 52ab, the third layer 52ac, and the fourth layer 52ad is the third layer 52ac.

The first portion 52a is not limited to a laminated structure, and may be a single layer film including only the first layer 52aa, or may be a laminated film including the first layer 52aa and the second layer 52ab.

The first portion 52a may be provided with an adhesion layer between the second layer 52ab and the third layer 52ac, and between the third layer 52ac and the fourth layer 52ad, respectively. In the present example embodiment, the adhesion layer includes, for example, Ti, but it is not limited to Ti. For example, an alloy of Ti or Cr may be used. An example alloy of Cr is NiCr.

The second portion 52b can be a laminated film. As shown in FIG. 1G, the second portion 52b includes a first layer 52ba, a second layer 52bb, and a third layer 52bc in this order from the first wiring electrode 7 side (upper side of FIG. 1G).

The material of the first layer 52ba can be, for example, Pt, W, Mo, Ta, Au, Cu, or alloys of these metals. In the present example embodiment, the first layer 52ba includes Au, for example.

The material of the second layer 52bb can be, for example, Pt, W, Mo, Ta, Au, Cu, or alloys of these metals. In the present example embodiment, the first layer 52bb includes Pt, for example.

The material of layer 52bc can be, for example, Cu, Al, or alloys of these metals. In the present example embodiment, the third layer 51ac include an alloy of Al, for example.

The layer closest to the first portion 52a of the second portion 52b (i.e., the first layer 52ba) includes Au, for example. That is, the first portion 52a and the second portion 52b each include a layer of Au and are connected to each other by the layer of Au. The second portion 52b includes a layer of Pt (i.e., the second layer 52bb) next to the layer of Au (i.e., the first layer 52ba).

The thickest of the first layer 52ba, the second layer 52bb, and the third layer 52bc is the third layer 52bc. The thickness is the length in the vertical direction of FIG. 1G.

The second portion 52b may be provided with an adhesion layer between the second layer 52ab and the third layer 52ac, and the third layer 52ac and the fourth layer 52ad, respectively. In the present example embodiment, for example, the adhesion layer includes Ti, but it is not limited to Ti, For example, an alloy of Ti or Cr may be used. An example alloy of Cr is NiCr.

The second portion 52b is not limited to a laminated structure, and may be a single layer film including only the first layer 52ba, or may be a laminated film including the first layer 52ba and the second layer 52bb.

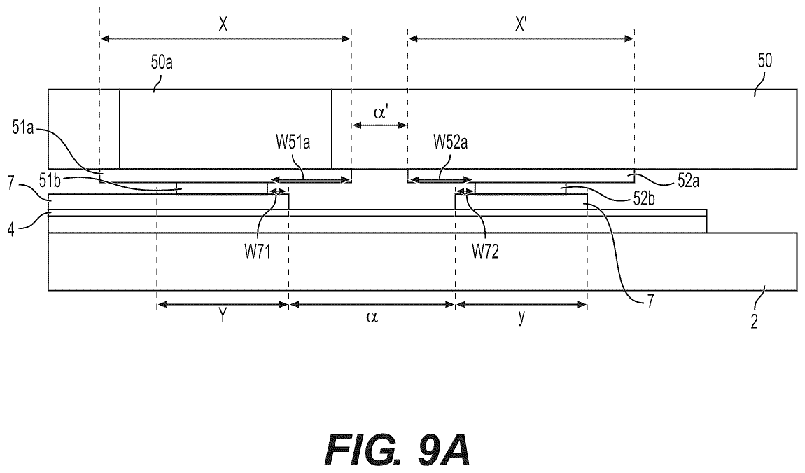

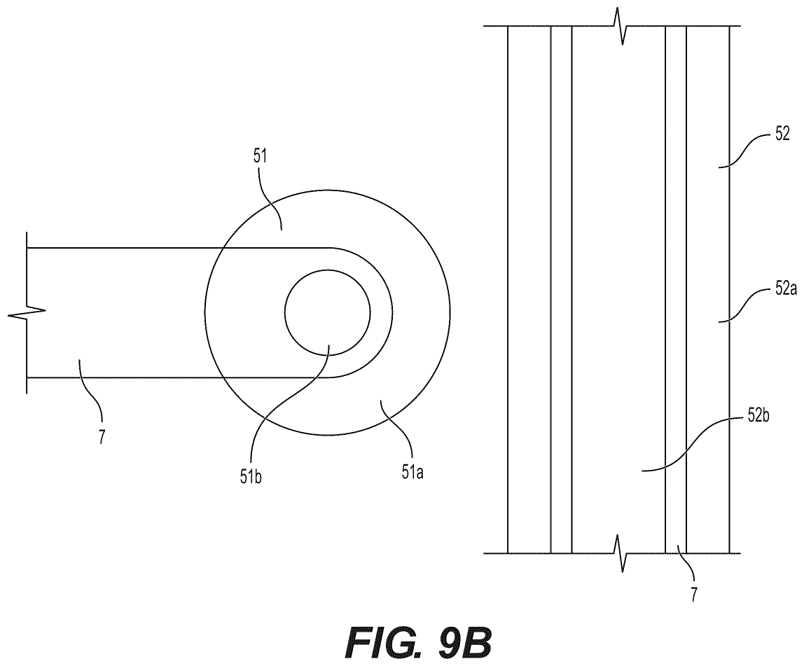

As seen in FIGS. 8A-9B, the width of the first portion 52a is larger than the width of the second portion 52b. The width of the portion of the first wiring electrode 7 facing the second portion 52b is smaller than the width of the first portion 52a and larger than the width of the second portion 52b. The width is the length in the left and right directions of FIGS. 8A-9B.

A dielectric layer 54 may be located between the lid 50 and the sealing frame 52. In the present example embodiment, the dielectric layer 54 includes silicon oxide, for example. The sealing frame 52 may further include an adhesion layer between the sealing frame 52 and the dielectric layer 54. In the present example embodiment, for example, the adhesion layer includes Ti, but it is not limited to Ti. For example, an alloy of Ti or Cr may be used. An alloy of Cr is, for example, NiCr.

The insulating layer 3 and the piezoelectric layer 4, and their respective end portions extend outside of the sealing frame 52 as shown in FIGS. 1A and 8. Outside the sealing frame 52, the ends of the insulating layer 3 and the piezoelectric layer 4 are inside the end of the support substrate 2. That is, the end of the support substrate 2 is exposed from the insulating layer 3 and the piezoelectric layer 4. A step is located at the end of the support substrate 2.

Unwanted capacitances may occur when two wirings or structures of different potentials are adjacent to each other, including, for example, when a signal wiring and a ground wiring are adjacent to each other. FIGS. 9A and 9B show a signal wiring (including the external terminal with via 50a is connected to the first wiring electrode 7 through the conductive wall 51) adjacent to a grounded structure (including sealing frame 52 connected to the first wiring electrode 7).

FIGS. 9A and 9B are a cross-sectional view and a plan view showing the first wiring electrode 7, the conductive wall 51, and the sealing frame 52. As shown in FIG. 9A, the first portion 51a of the conductive wall 51 has a diameter X and includes an extending portion that extends past the end of the second portion 52 closest to the sealing frame 52 towards the sealing frame 52 with a width W51a. The first wiring electrode 7 includes a first extending portion that extends past the end of the second portion 52 closest to the sealing frame 52 toward the sealing frame 52 with a width W71. The width W51a of the extending portion of the first portion 51a is larger than the width W71 of the first extending portion of the first wiring electrode 7. The widths W51a and W71 are the widths from the contact points with the second portion 51b to the ends of the respective extending portions. As shown in the plan view of FIG. 9B, the first wiring electrode 7 ends with a semicircle underneath the conductive wall 51. The radius of the first portion 51a (=to X/2) is larger than the radius of the semicircle at the end of the first wiring electrode 7 (=Y/2). In other words, the diameter X of the first portion 51a is larger than the diameter Y of the semicircle at the end of the first wiring electrode 7.

The first portion 52a of the sealing frame 52 has a width x′ and includes an extending portion that extends past the end of second portion 52b towards the conductive wall 51 with a width W52a. The first wiring electrode 7 has a width y′ and includes a second extending portion that extends past the end of second portion 52b towards the conductive wall 51 with a width W72. The width W52a of the extending portion of the first portion 52a is larger than the width W72 of the second extending portion of the first wiring electrode 7. The widths W52a and W72 are the lengths from the contacts with the second portion 52b to the ends of the respective extending portions. As shown in FIG. 9A, the width x′ of the first portion 52a of the sealing frame 52 is larger than the width y′ of the first wiring electrode 7.

As shown in FIG. 9A, the first portion 51a of the conductive wall 51 and the first portion 52a of the sealing frame 10 can be spaced apart by a distance α′, and the closest portions of the first wiring electrode 7 can be spaced apart by a distance α along the surface of the piezoelectric layer 4 (or any high relative permittivity film if using). The distance α can be maximized. If the permittivity on the device side (e.g., the composite dielectric constant of the support substrate 2 and the piezoelectric layer 4) is εα and if the permittivity of the lid 50 is εα′, then the relationship εα>εα′ can be satisfied. In addition, the relationship α/α′≥εα/εα′ can be satisfied to reduce unwanted capacitance.

The piezoelectric layer 4 continuously extends between the first and second extending portions of the first wiring electrode 7. The relative permittivity of the piezoelectric layer 4 is typically greater that than the relative permittivity of the lid 50, which can increase the capacitive coupling along the piezoelectric layer 4 compared to along the lid 50. When the dielectric constant of the lid 50 is lower than the dielectric contact of the piezoelectric layer 4, the width α of the region between the first extending portion and the second extending portion can be maximized while the distance α′ between the conductive wall 51 and the sealing frame 52 is minimized, thus reducing or preventing capacitive coupling between the conductive wall 51 and the sealing frame 52 by increasing the distance along piezoelectric layer 4 compared to the distance along the lid 50.

When the dielectric constant of the lid 50 and the piezoelectric layer 4 is inversely related, the capacitance coupling can be reduced or prevented by reversing the relationship between the width of the extending portion of the first portion 51a of the conductive wall 51 and the width of the first wiring electrode 7, and the relationship between the width of the extending portion of the first portion 52a of the sealing frame 52 and the width of the first wiring electrode 7. That is, the width W51a of the extending portion of the first portion 51a of the conductive wall 51 is smaller than the width W71 of the first extending portion of the first wiring electrode 7, and the width W52a of the extending portion of the first portion 52a of the sealing frame 52 is smaller than the width W72 of the second extending portion of the first wiring electrode 7, thus reducing or preventing capacitive coupling.

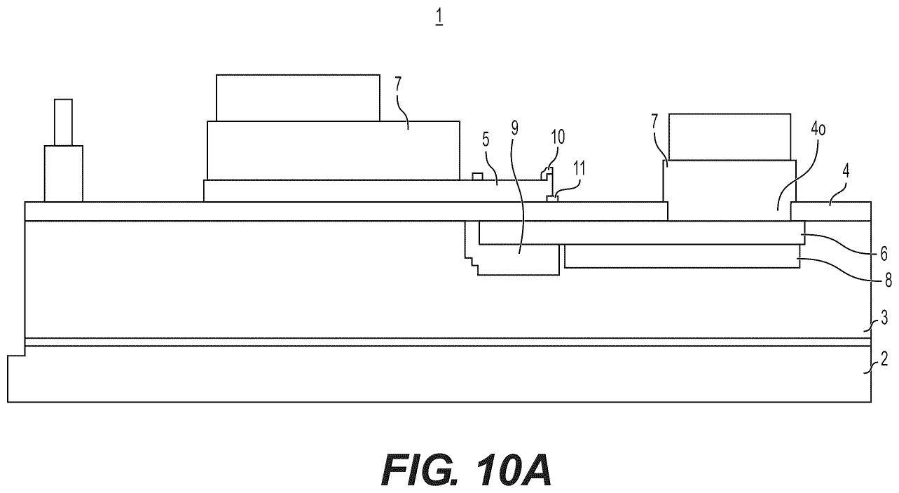

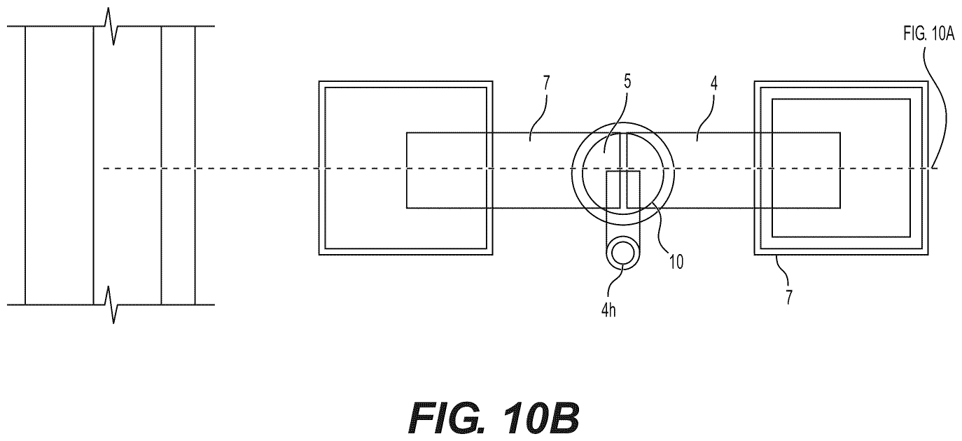

FIGS. 10A and 10B show a cross-sectional view of another example embodiment of the elastic wave device 1. In the present example embodiment, the piezoelectric layer 4 includes an opening 40 sandwiched by the first wiring electrode 7 and the second wiring electrode 8. As shown in FIG. 10A, the second excitation electrode 6 can be located between the first wiring electrode 7 and the second wiring electrode 8 in the opening 40. The opening 40 exists in a region of the piezoelectric layer 4 sandwiched between the first wiring electrode 7 and the second wiring electrode 8. That is, the opening 40 does not overlap the cavity 9 (or the recess 3a). The opening 40 is filled with a conductor. In the present example embodiment, the wiring electrode 7 is filled as a conductor.

The present example embodiments include one or more of the following structures/features.

The piezoelectric layer 4 is pyro-free.

The first frame 10 is located along the excitation region A. The first frame 10 may be located on the first excitation electrode 5 or between the first excitation electrode 5 and the piezoelectric layer 4. The first frame 10 may be a jagged frame. A cantilever structure may be defined by the first frame 10. A plurality of first frames 10 may be included, and at least a portion of the plurality of first frames 10 may overlap. The first frame 10 may be metal or silicon oxide. The arrangement, shape, and materials of the first frames 10 can be appropriately combined.

The first wiring electrode 7 is connected to an external terminal.

The total area of the first excitation electrode 5 and the first wiring electrode 7 is larger than the total area of the second excitation electrode 6 and the second wiring electrode 8.

The etching holes 9 can be aligned in a direction where the coefficient of linear expansion of the piezoelectric layer 4 is largest.

The first excitation electrode 5 includes a first layer 5a and a second layer 5b. The second excitation electrode 6 includes a first layer 6a and a second layer 6b. The materials and thicknesses of the first layer 5a, the second layer 5b, the first layer 6a, and the second layer 6b are as described above.

The second wiring electrode 8 may extend across two second excitation electrodes 6 of an adjacent excitation regions A. In this case, the second wiring electrode 8 can be thicker than the two second excitation electrodes 6.

The width W51a of the extending portion of the first portion 51a of the conductive wall 51 is larger than the width of the first extending portion W71 of the first wiring electrode 7. The width W52a of the extending portion of the first portion 52a of the sealing frame 52 is larger than the width W72 of the second extending portion of the first wiring electrode 7.

The recess 3a has a tapered shape toward the bottom surface 3aa.

The second wiring electrode 8 is located outside the cavity 9.

The second wiring electrode 8 is embedded in the insulating layer 3. That is, one surface of the second wiring electrode 8 is surrounded by the second excitation electrode 6, and the remaining surfaces of the second wiring electrode 8 are surrounded by the insulating layer 3.

The step 3ac follows the step defined by the second excitation electrode 6 and the piezoelectric layer 4.

The first wiring electrode 7 is located outside the cavity 9.

The thickness of the first wiring electrode 7 is thicker than that of the second wiring electrode 8.

The first portion 51a and the second portion 51b of the conductive wall 51 each include a layer of Au, and the layers of Au are connected to each other. The first portion 52a and the second portion 52b of the sealing frame 52 each include a layer of Au, and the layers of Au are connected to each other.

The first portion 51a of the conductive wall 51 includes a layer of Pt next to a layer of Au. The second portion 51b also includes a layer of Pt next to a layer of Au. The first portion 52a of the sealing frame 52 includes a layer of Pt next to a layer of Au. The second portion 52b of the sealing frame 52 includes a layer of Pt next to a layer of Au.

A dielectric layer 53 is located between the lid 50 and the conductive wall 51. A dielectric layer 54 is located between the lid 50 and the sealing frame 52.

The width of the first portion 52a of the sealing frame 52 is larger than the width of the second portion 52b. The width of the portion of the first wiring electrode 7 facing the first portion 52b is smaller than the width of the first portion 52a and larger than the width of the second portion 52b.

The tapered shape of the first portion 51a is opposite to that of the second portion 51b and the first wiring electrode 7 such that the first portion 51a narrows towards the second portion 51b and such that the second portion 51b narrows towards the first portion 51a. The tapered shape of the first portion 52a is opposite to that of the second portion 52b and the first wiring electrode 7 such that the first portion 52a narrows towards the second portion 52b and such that the second portion 52b narrows towards the first portion 52a.

A step is located at the end of the support substrate 2.

A dielectric layer 56 may be disposed between the via 50a and the lid 50. The dielectric is, for example, silicon oxide.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
an insulating layer including a recess;
a piezoelectric layer on the insulating layer and over the recess to define a cavity;
a first excitation electrode on a first surface of the piezoelectric layer opposite to the cavity;
a second excitation electrode within the cavity and on a second surface of the piezoelectric layer opposite to the first surface;
a wiring electrode on the piezoelectric layer and connected to the first excitation electrode;
a lid;
a conductive wall extending between a first portion of the wiring electrode and the lid and including a first portion and a second portion; and
a sealing frame extending between a second portion of the wiring electrode and the lid, the sealing frame including:
a first portion with a first width; and
a second portion with a second width smaller than the first width; wherein
a third width of the second portion of the wiring electrode is smaller than the first width of the first portion of the sealing frame and is larger than the second width of the second portion of the sealing frame.

2. The acoustic wave device of claim 1, further comprising:
a first dielectric layer between the lid and the conductive wall; and
a second dielectric layer between the lid and the sealing frame.

3. The acoustic wave device of claim 1, wherein
the first portion of the conductive wall has a tapered shape that narrows towards the second portion of the conductive wall;
the second portion of the conductive wall has a tapered shape that narrows towards the first portion of the conductive wall;
the first portion of the sealing frame has a tapered shape that narrows towards the second portion of the sealing frame; and
the second portion of the sealing frame has a tapered shape that narrows towards the first portion of the sealing frame.

4. The acoustic wave device of claim 1, wherein the lid includes a via connected to the first portion of the conductive wall.

5. The acoustic wave device of claim 4, further comprising a third dielectric layer between the via and the lid.

6. The acoustic wave device of claim 5, wherein the third dielectric layer includes silicon oxide.

7. The acoustic wave device of claim 1, wherein
the first portion of the conductive wall includes multiple layers that include a first gold layer;
the second portion of the conductive wall includes multiple layers that include a second gold layer directly connected to the first gold layer of the first portion of the conductive wall;
the first portion of the sealing frame includes multiple layers that include a third gold layer; and
the second portion of the sealing frame includes multiple layers that include a fourth gold layer directly connected to the third gold layer of the first portion of the sealing frame.

8. The acoustic wave device of claim 1, wherein
the first portion of the conductive wall includes an extending portion that extends past an end of the second portion of the conductive wall closest to the sealing frame towards the sealing frame with a fourth width;
the wiring electrode includes a first extending portion that extends past the end of the second portion of the conductive wall closest to the sealing frame toward the sealing frame with a fifth width that is less than the fourth width;
the first portion of the sealing frame includes an extending portion that extends past an end of the second portion of the sealing frame towards the conductive wall with a sixth width; and
the wiring electrode includes a second extending portion that extends past the end of the second portion of the sealing frame towards the conductive wall with a seventh width that is less than the sixth width.

9. The acoustic wave device of claim 1, wherein
the first portion of the conductive wall includes a first platinum layer adjacent to a first gold layer;
the second portion of the conductive wall includes a second platinum layer adjacent to a second gold layer;
the first portion of the sealing frame includes a third platinum layer adjacent to a third gold layer; and
the second portion of the sealing frame includes a fourth platinum layer adjacent to a fourth gold layer.

10. The acoustic wave device of claim 1, further comprising:
a support substrate on which the insulating layer is located; wherein
the support substrate includes a step at an end of the support substrate.

11. The acoustic wave device of claim 1, further comprising:
a dielectric layer on the first excitation electrode; and
a first frame on the second excitation electrode and within the cavity.

12. The acoustic wave device of claim 11, wherein the first frame includes first width portions and second width portions different from the first width portions.

13. The acoustic wave device of claim 11, further comprising a second frame on the second excitation electrode.

14. The acoustic wave device of claim 13, wherein
the second frame is on a first surface of the second excitation electrode between the piezoelectric layer and the second excitation electrode; and
the first frame is on a second surface of the second excitation electrode opposite to the first surface of the second excitation electrode.

15. The acoustic wave device of claim 14, further comprising an excitation region defined by an overlap region, when viewed in a plan view, between the first and the second excitation electrodes.

16. The acoustic wave device of claim 15, wherein the second frame includes a cantilever that extends past an end of the second excitation electrode.

17. The acoustic wave device of claim 16, wherein
the first frame has a constant width and extends along an entire periphery of the excitation region; and
the second frame has a constant width and extends along a portion of the entire periphery of the excitation region.

18. The acoustic wave device of claim 16, wherein
the first frame alternates between a first width and a second width different than the first width and extends along an entire periphery of the excitation region; and
the second frame has a constant width and extends along the entire periphery of the excitation region.

19. The acoustic wave device of claim 16, wherein
the first frame has a constant width and extends along a first portion of an entire periphery of the excitation region; and
the second frame has a constant width and extends along a second portion of the entire periphery of the excitation region.

20. The acoustic wave device of claim 16, wherein
the first frame alternates between a first width and a second width different than the first width and extends along a first portion of an entire periphery of the excitation region; and
the second frame has a constant width and extends along a second portion of the entire periphery of the excitation region.
